(19) United States
(12) Patent Application Publication
(10) Pub. No.: US 2026/0362828 A1
(43) Pub. Date: Nov. 12, 2026

(54) PHOTODETECTION DEVICE, METHOD FOR MANUFACTURING THE SAME, AND ELECTRONIC DEVICE

(71) Applicant: SONY SEMICONDUCTOR SOLUTIONS CORPORATION, KANAGAWA (JP)

(72) Inventor: HIROYUKI HATTORI, KANAGAWA (JP)

(21) Appl. No.: 19/109,215

(22) PCT Filed: Sep. 15, 2022
(86) PCT No.: PCT/JP2022/034521

§ 371 Date: Mar. 6, 2025

(51) Int. Cl. H10F 39/18; G01S 7/4913; G01S 7/4915; G01S 17/36; H10F 39/00

(52) U.S. Cl. CPC H10F 39/1843; G01S 7/4913; G01S 7/4915; G01S 17/36; H10F 39/014; H10F 39/018; H10F 39/8037; H10F 39/806; H10F 39/807; H10F 39/809

(57) ABSTRACT

The present disclosure relates to a photodetection device that enables implementation of a photoelectric conversion section having a high quantum efficiency in an infrared region, a method for manufacturing the photodetection device, and an electronic device. The photodetection device includes: a silicon germanium layer on which a photoelectric conversion section is formed; an inter-pixel light shielding film formed on a first surface side that is a light incident surface side of the silicon germanium layer; and a MOS transistor formed on a second surface side that is an opposite side of the silicon germanium layer from the first surface, in which a germanium concentration of the silicon germanium layer is formed at a constant concentration. The technology of the present disclosure can be applied to, for example, a ToF sensor, an imaging sensor, and the like.

### TECHNICAL FIELD

The present disclosure relates to a photodetection device, a method for manufacturing the photodetection device, and an electronic device, and more particularly, to a photodetection device, a method for manufacturing the photodetection device, and an electronic device enabled to implement a photoelectric conversion section having a high quantum efficiency in an infrared region.

### BACKGROUND ART

Conventionally, in a case where a silicon substrate is used as a substrate material of a CMOS image sensor, an absorption wavelength band in a near infrared region is about 1 um, and an absorption coefficient decreases toward the near infrared region. Thus, in order to increase the quantum efficiency at a wavelength greater than or equal to 900 nm, which cannot be implemented by silicon, it has been studied to introduce germanium (Ge) or silicon germanium (SiGe) instead of silicon (Si) as a composition of a photodiode. When a compound semiconductor substrate such as silicon germanium is used, the absorption coefficient in the infrared region is increased, so that sensitivity is improved. In particular, in the silicon germanium substrate, it is possible to change the absorption wavelength band up to about 1.9 um by changing a Ge composition, and it is possible to manufacture a sensor having a high absorption coefficient in the infrared region by performing composition design according to a purpose.

When a SiGe layer is formed on a Si substrate, distortion and stress are generated due to a mismatch of lattice constants between Si and Ge, whereby crystal defects are generated. In order to prevent this, a SiGe stress relieving layer having a Ge concentration gradient needs to be formed between a SiGe epitaxial layer and the Si substrate. For example, Patent Document 1 discloses a front-illuminated type sensor structure provided with the SiGe stress relieving layer.

### CITATION LIST

### Patent Document

### Patent Document 1: Japanese Patent Application Laid-Open No. 2007-13177

### SUMMARY OF THE INVENTION

### Problems to be Solved by the Invention

In the sensor structure of Patent Document 1, in order to suppress a dark current, in the SiGe layer, a high-concentration P-type layer is provided in which a high-concentration P-type impurity is injected, and a process of injecting the P-type impurity is required for forming the high-concentration P-type layer. Furthermore, it is desirable to remove the SiGe stress relieving layer from a viewpoint of suppressing the dark current.

The present disclosure has been made in view of such a situation, and enables implementation of a photoelectric conversion section having a high quantum efficiency in an infrared region.

### Solutions to Problems

A photodetection device of a first aspect of the present disclosure is a photodetection device including:
a silicon germanium layer on which a photoelectric conversion section is formed;
an inter-pixel light shielding film formed on a first surface side that is a light incident surface side of the silicon germanium layer; and
a MOS transistor formed on a second surface side that is an opposite side of the silicon germanium layer from the first surface, in which
a germanium concentration of the silicon germanium layer is formed at a constant concentration.

A method for manufacturing a photodetection device of a second aspect of the present disclosure is a method for manufacturing a photodetection device, the method including:
forming a photoelectric conversion section in a silicon germanium layer;
forming an inter-pixel light shielding film on a first surface side that is a light incident surface side of the silicon germanium layer; and
forming a MOS transistor on a second surface side that is an opposite side of the silicon germanium layer from the first surface, in which
a germanium concentration of the silicon germanium layer is formed at a constant concentration.

An electronic device of a third aspect of the present disclosure is an electronic device including
a photodetection device including:
a silicon germanium layer on which a photoelectric conversion section is formed;
an inter-pixel light shielding film formed on a first surface side that is a light incident surface side of the silicon germanium layer; and
a MOS transistor formed on a second surface side that is an opposite side of the silicon germanium layer from the first surface, in which
a germanium concentration of the silicon germanium layer is formed at a constant concentration.

In the first to third aspects of the present disclosure, provided are the silicon germanium layer on which the photoelectric conversion section is formed, the inter-pixel light shielding film formed on the first surface side that is the light incident surface side of the silicon germanium layer, and the MOS transistor formed on the second surface side that is the opposite side of the silicon germanium layer from the first surface, in which the germanium concentration of the silicon germanium layer is formed at the constant concentration.

The photodetection device and the electronic device may be independent devices or may be modules incorporated in another device.

### BRIEF DESCRIPTION OF DRAWINGS

FIG. 1 is a cross-sectional view illustrating a configuration example of a photodetection device that is an embodiment of the present disclosure.

FIG. 2 is a diagram for explaining a method for manufacturing the photodetection device of FIG. 1.

FIG. 3 is a diagram illustrating a pixel circuit example in a case where the photodetection device is a gate type ToF sensor.

FIG. 4 is a cross-sectional view of a pixel in the case where the photodetection device is the gate type ToF sensor.

FIG. 5 is a diagram illustrating a pixel circuit example in a case where the photodetection device is an IR imaging sensor.

FIG. 6 is a cross-sectional view of a pixel in the case where the photodetection device is the IR imaging sensor.

FIG. 7 is a diagram illustrating a pixel circuit example in a case where the photodetection device is a CAPD type ToF sensor.

FIG. 8 is a cross-sectional view of a pixel in the case where the photodetection device is the CAPD type ToF sensor.

FIG. 9 is a diagram illustrating a pixel circuit example in a case where the photodetection device is a direct ToF sensor using a SPAD.

FIG. 10 is a cross-sectional view of a pixel in the case where the photodetection device is the direct ToF sensor using the SPAD.

FIG. 11 is a cross-sectional view of a pixel in which a diffraction structure is added to the back surface of the SiGe layer in FIG. 10.

FIG. 12 is a plan view of the diffraction structure of FIG. 11.

FIG. 13 is a cross-sectional view of a pixel in which the diffraction structure is added to the front surface of the SiGe layer in FIG. 10.

FIG. 14 is a diagram illustrating a modification of an element separation section.

FIG. 15 is a diagram illustrating an example of a diffraction structure by the same forming method as that for the element separation section.

FIG. 16 is a block diagram illustrating a schematic configuration example of the photodetection device of the present disclosure.

FIG. 17 is a diagram illustrating a usage example of an image sensor using the photodetection device.

FIG. 18 is a block diagram illustrating a configuration example of an imaging device as an electronic device to which the technology of the present disclosure is applied.

FIG. 19 is a diagram illustrating an example of a schematic configuration of an endoscopic surgery system.

FIG. 20 is a block diagram illustrating an example of a functional configuration of a camera head and a CCU.

FIG. 21 is a block diagram illustrating an example of a schematic configuration of a vehicle control system.

FIG. 22 is an explanatory diagram illustrating an example of installation positions of an outside-vehicle information detecting section and an imaging section.

### MODE FOR CARRYING OUT THE INVENTION

Hereinafter, modes for carrying out the technology of the present disclosure (hereinafter, referred to as embodiments) will be described with reference to the accompanying drawings.

The description will be given in the following order.
1. Cross-sectional view of photodetection device of present disclosure
2. Method for manufacturing photodetection device
3. Pixel configuration example in case where photodetection device is gate type ToF sensor
4. Pixel configuration example in case where photodetection device is imaging sensor
5. Pixel configuration example in case where photodetection device is CAPD type ToF sensor
6. Pixel configuration example in case where photodetection device is direct ToF sensor using SPAD
7. Modification with added diffraction structure
8. Modification of element separation section
9. Configuration example of photodetection device
10. Usage example of photodetection device as image sensor
11. Application example to electronic device
12. Application example to endoscopic surgery system
13. Application example to mobile body

Note that, in the drawings to be referred to in the description below, the same or similar portions are denoted by the same or similar reference signs, and explanation thereof will not be repeated as appropriate. The drawings are schematic, and the relationship between the thickness and the planar dimension, the ratio of the thickness of each layer, and the like differ from the actual ones. Furthermore, the drawings may include portions having different dimensional relationships and ratios in some cases.

Furthermore, definition of directions such as upward and downward directions, and the like in the following description is merely the definition for ease of explanation, and does not limit the technical idea of the present disclosure. For example, when an object is rotated by 90° to be observed, the upper and lower sides are changed as the left and right sides, and, when the object is rotated by 180° to be observed, the upper and lower sides are reversed.

### 1. Cross-Sectional View of Photodetection Device of Present Disclosure

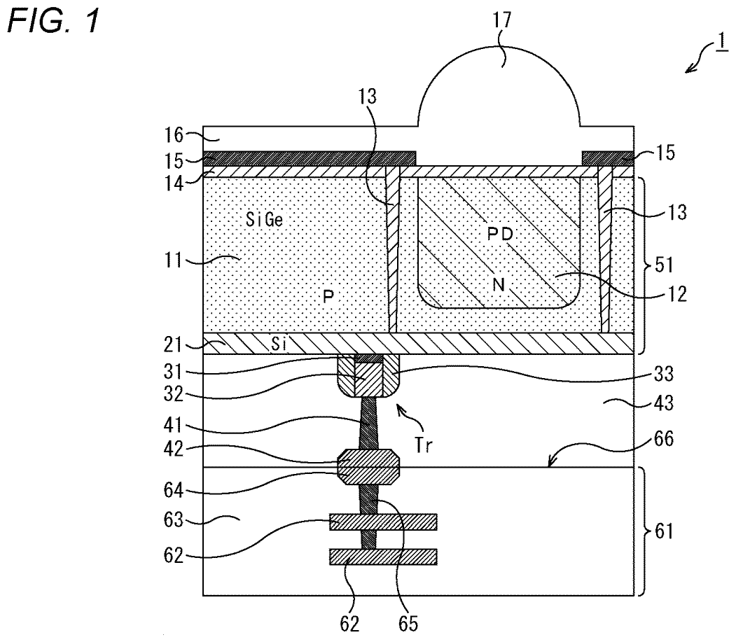

FIG. 1 is a cross-sectional view illustrating a configuration example of a photodetection device that is an embodiment of the present disclosure.

A photodetection device 1 illustrated in FIG. 1 includes a photoelectric conversion section having a high quantum efficiency (QE) for light in an infrared region. Specifically, a photodiode (PD) 12 as a photoelectric conversion section is formed in a SiGe layer 11.

The SiGe layer (silicon germanium layer) 11 is a single crystal layer of silicon germanium (SiGe) in which a germanium concentration is formed at a constant concentration. Here, “constant” of the constant concentration is defined as that a variation in germanium concentration in a layer is controlled to a value of at least smaller than 10% of a target concentration, and typically about ±1%. An absolute value of the germanium concentration is not limited to a predetermined range, and may be, for example, about 20 to 30% or about 70 to 80%. As the germanium concentration is increased, a higher absorption coefficient can be provided in the infrared region. The SiGe layer 11 includes a low-concentration P-type semiconductor region, and an N-type semiconductor region doped with an N-type impurity such as phosphorus (P) or arsenic (As) is formed in a partial region of the SiGe layer 11, whereby the photodiode 12 of a PN junction type is formed.

An antireflection film 14 is formed on the upper surface of the back surface of the SiGe layer 11, which is a surface of the upper side of the SiGe layer 11 in FIG. 1, and a light shielding film 15 and a lens layer 16 are formed in order on the upper side of the antireflection film 14. The lens layer 16 is formed flat on the upper portion of the SiGe layer 11 on which the photodiode 12 is not formed, for example, the outer peripheral portion outside a pixel array unit, or the like, but an on-chip lens 17 is formed on the upper portion of the SiGe layer 11 on which the photodiode 12 is formed. The antireflection film 14 can include for example, a stacked structure in which a fixed charge film and an oxide film are stacked, and it is possible to use, for example, an insulating thin film having a high dielectric constant (High-k) by an atomic layer deposition (ALD) method. Specifically, as the fixed charge film, it is possible to use hafnium oxide (HfO₂), aluminum oxide (Al₂O₃), titanium oxide (TiO₂), strontium titan oxide (STO), or the like. A material of the light shielding film 15 may be any material as long as it shields light, and it is possible to use a metal material, for example, tungsten (W), aluminum (Al), copper (Cu), or the like. The lens layer 16 includes a resin material, for example, a styrene resin, an acrylic resin, a styrene-acrylic copolymer resin, or a siloxane resin. The on-chip lens 17 condenses incident light and causes the incident light to efficiently enter the photodiode 12.

In the SiGe layer 11, an element separation section 13 is formed around the photodiode 12 in plan view. The element separation section 13 penetrates the SiGe layer 11 and performs electrical separation from other adjacent photoelectric conversion sections (photodiodes 12). The element separation section 13 is formed such that a metal material, for example, tungsten (W), aluminum (Al), titanium (Ti), titanium nitride (TiN), or the like, is embedded inside a trench formed so as to penetrate the SiGe layer 11. Alternatively, the element separation section 13 may be formed such that at least one layer of the antireflection film 14 formed on the back surface of the SiGe layer 11 is formed on a sidewall of the trench formed in the SiGe layer 11, and an insulating film such as a silicon oxide film is embedded inside the antireflection film 14.

A Si layer (silicon layer) 21 is formed on the upper surface (lower surface in FIG. 1) of the front surface of the SiGe layer 11, which is a surface of the lower side of the SiGe layer 11 in FIG. 1. The Si layer 21 is a cap layer of silicon (Si) covering the SiGe layer 11, and has a function of preventing germanium contamination during manufacturing. The Si layer 21 is formed to have a film thickness of, for example, about 10 nm.

The upper surface (lower surface in FIG. 1) of the Si layer 21 is a transistor formation surface in a case where a MOS transistor is formed, and in the example of FIG. 1, one MOS transistor Tr is formed. However, the MOS transistor Tr is not necessarily formed on the upper surface of the Si layer 21. Alternatively, two or more MOS transistors Tr may be formed on the upper surface of the Si layer 21. The MOS transistor Tr includes a gate insulating film 31, a gate electrode 32 formed thereon, and a sidewall 33 formed on a sidewall of the gate electrode 32. The gate electrode 32 of the MOS transistor Tr is connected to a bonding electrode 42 via a contact electrode 41, and the bonding electrode 42 is connected by metal bonding to a bonding electrode 64 of a wiring layer 61 of another semiconductor substrate (not depicted) stacked. An insulating layer 43 is formed on the upper surface of the Si layer 21 where the MOS transistor Tr is not formed.

The photodetection device 1 includes a stacked structure of a semiconductor substrate (compound semiconductor substrate) 51 including the SiGe layer 11 and the Si layer 21, and a semiconductor substrate (Hereinafter, it is referred to as a logic substrate.) not depicted in which at least a logic circuit is formed. However, in FIG. 1, only the wiring layer 61 is depicted for the logic substrate. In FIG. 1, a light incident surface side of the semiconductor substrate 51 including the SiGe layer 11 and the Si layer 21 is the back surface (first surface) of the semiconductor substrate 51, and a side connected to the logic substrate is the front surface (second surface) of the semiconductor substrate 51. In the logic substrate, formed are a plurality of MOS transistors Tr, a drive circuit for the MOS transistors Tr, and a signal processing circuit that processes a signal corresponding to charges generated by the photodiode 12. A drive circuit for the MOS transistor Tr formed on the Si layer 21 is also formed on the logic substrate side. The antireflection film 14, the light shielding film 15, and the lens layer 16 are formed on the back surface side of the semiconductor substrate 51, and a plurality of MOS transistors Tr (including those formed on the logic substrate) is formed on the front surface side of the semiconductor substrate 51. Note that the antireflection film 14, the light shielding film 15, and the lens layer 16 formed on the back surface side of the semiconductor substrate 51 may be appropriately omitted according to design conditions.

The wiring layer 61 includes a plurality of layers of metal wiring lines 62 and an insulating layer 63. In the example of FIG. 1, the number of layers of the metal wiring lines 62 is two, but the number of layers of the metal wiring lines 62 is not limited. Furthermore, the bonding electrode 64 is formed on a bonding surface 66 with the insulating layer 43, which is the upper surface of the wiring layer 61, and the bonding electrode 64 is electrically connected to the bonding electrode 42 by metal bonding. The bonding electrode 64 is connected to a predetermined metal wiring line 62 via a contact electrode 65. As a material of the contact electrode 41, the bonding electrode 42, the bonding electrode 64, the contact electrode 65, and the metal wiring line 62, for example, copper (Cu), tungsten (W), aluminum (Al), gold (Au), or the like can be adopted, but in the present embodiment, copper is adopted. Thus, the bonding electrode 42 and the bonding electrode 64 form Cu—Cu bonding. The insulating layers 43 and 63 include, for example, a SiO2 film, a Low-k film (low dielectric constant insulating film), a SiOC film, or the like. The insulating layers 43 and 63 may include a plurality of insulating films including different materials.

As described above, the photodetection device 1 includes the photodiode 12 as the photoelectric conversion section, and the photodiode 12 is formed only in the SiGe layer 11 having good crystallinity and a constant germanium concentration. Since the photodiode 12 formed in the SiGe layer 11 has a high absorption coefficient in the infrared region, sensitivity to light in the infrared region is improved. Furthermore, the photodetection device 1 has a back-illuminated type structure in which the on-chip lens 17 is formed on the back surface side of the semiconductor substrate 51 including the SiGe layer 11, and the light condensed by the on-chip lens 17 is photoelectrically converted by the photodiode 12. The back-illuminated type structure can increase an opening area to the photodiode 12 as compared with a front-illuminated type structure, and can improve the sensitivity. Thus, according to the photodetection device 1, it is possible to implement a photoelectric conversion section having a high quantum efficiency in the infrared region.

Since a structure of the semiconductor substrate 51 included in the photodetection device 1 does not include a SiGe stress relieving layer, it is possible to suppress a dark current generated due to a crystal defect of the SiGe stress relieving layer. Furthermore, it is not necessary to provide a high-concentration P-type layer for dark current suppression in a case where the SiGe stress relieving layer is provided as in the sensor structure of Patent Document 1.

### 2. Method for Manufacturing Photodetection Device

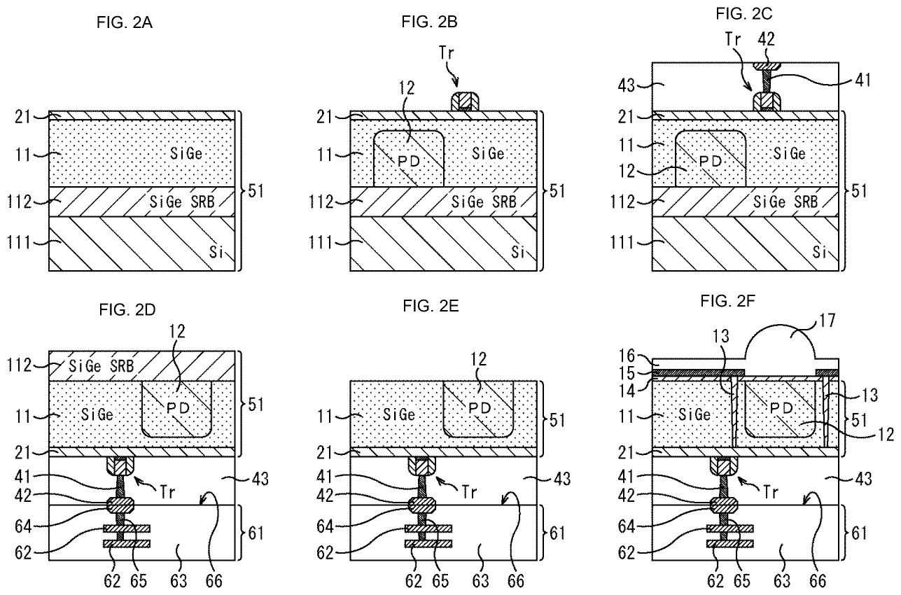

Next, a method for manufacturing the photodetection device 1 of FIG. 1 will be described with reference to FIG. 2.

First, as illustrated in A of FIG. 2, a SiGe heteroepitaxial substrate is prepared as the semiconductor substrate 51 including the SiGe layer 11 and the Si layer 21. The SiGe heteroepitaxial substrate prepared as the semiconductor substrate 51 in a state of A of FIG. 2 is a substrate in which a SiGe stress relieving layer (SiGe SRB) 112 for suppressing crystal defects, the SiGe layer 11 having no crystal defect, and the Si layer 21 are stacked on a silicon substrate 111. The SiGe heteroepitaxial substrate can be formed by epitaxial growth of the SiGe stress relieving layer 112, the SiGe layer 11, and the Si layer 21 in this order on the silicon substrate 111.

Next, as illustrated in B of FIG. 2, an N-type semiconductor region is formed by doping of an N-type impurity such as phosphorus in a desired region of the SiGe layer 11 including the P-type semiconductor region, and the photodiode 12 of the PN junction type is formed. Moreover, the MOS transistor Tr is formed at a desired position on the upper surface of the Si layer 21. In the formation of the MOS transistor Tr, first, an insulating film to be the gate insulating film 31 is formed on the entire upper surface of the Si layer 21, and then the insulating film on positions other than a position where the MOS transistor Tr is to be formed is removed by a lithography technology to form the gate insulating film 31. Thereafter, the gate electrode 32 and the sidewall 33 are formed. The gate electrode 32 includes, for example, polysilicon, and the sidewall 33 includes, for example, a silicon nitride film (SiN) or the like. Note that, in FIG. 2, reference signs of the gate insulating film 31, the gate electrode 32, and the sidewall 33 are omitted.

Next, as illustrated in C of FIG. 2, the insulating layer 43 is formed with a predetermined film thickness on the upper surface of the Si layer 21 so as to cover the gate electrode 32 and the like of the MOS transistor Tr, and then the upper portion of the gate electrode 32 is opened and a predetermined metal material such as copper is embedded to form the contact electrode 41 and the bonding electrode 42.

Next, the insulating layer 43 formed on the semiconductor substrate 51 and the wiring layer 61 of the logic substrate separately manufactured are bonded together at the bonding surface 66, and then turned upside down as illustrated in D of FIG. 2. After being turned upside down, the silicon substrate 111 to be the uppermost layer of the semiconductor substrate 51 is removed by chemical mechanical polishing (CMP) or the like.

Next, as illustrated in E of FIG. 2, the SiGe stress relieving layer 112 to be the uppermost layer of the semiconductor substrate 51 is removed by CMP or the like. As a result, the semiconductor substrate 51 includes the SiGe layer 11 and the Si layer 21, and is in a state where the photodiode 12 is formed in the SiGe layer 11.

Finally, as illustrated in F of FIG. 2, the antireflection film 14 is formed on the upper surface of the SiGe layer 11, and then the element separation section 13 is formed. Subsequently, the light shielding film 15 and the lens layer 16 including the on-chip lens 17 are formed in order, whereby a cross-sectional structure of the photodetection device 1 illustrated in FIG. 1 is completed.

According to the method for manufacturing the photodetection device 1 described above, since the SiGe stress relieving layer 112 having many crystal defects is removed, it is not necessary to provide the high-concentration P-type layer for dark current suppression required in the sensor structure of Patent Document 1. As a result, an impurity injection process becomes unnecessary for forming a high-concentration P-type layer for dark current suppression. Furthermore, in order to form the high-concentration P-type layer, it is necessary to inject impurities with high energy into a deep region, and the SiGe layer may be damaged by the impurity injection process with high energy; however, since the high-concentration P-type layer is unnecessary, such damage can be avoided.

Since the upper surface of the SiGe layer 11 to be a MOS transistor formation surface is covered with the Si layer 21, germanium contamination during manufacturing can be prevented. Furthermore, since an oxide film to be the gate insulating film 31 of the MOS transistor Tr can be formed on the Si layer 21, an interface level of an interface of the gate insulating film 31 during MOS transistor formation can be reduced as compared with a case where the oxide film is formed on the upper surface of the SiGe layer 11.

### 3. Pixel Configuration Example in Case Where Photodetection Device is Gate Type ToF Sensor

The photodetection device 1 described above may be a time of flight (ToF) sensor that measures a distance to an object by using irradiation light, or an imaging sensor that receives light including at least infrared light and generates an image corresponding to a received light amount. Hereinafter, pixel structures in a case where the photodetection device 1 is various ToF sensors or imaging sensors will be described in order.

The ToF sensor is a sensor that measures the distance to the object by measuring a time from when irradiation light is emitted toward the object to when the irradiation light is reflected on a surface of the object and returned. ToF sensors include an indirect ToF sensor and a direct ToF sensor. The indirect ToF sensor detects a flight time from when irradiation light is emitted to when reflected light is received as a phase difference and calculates the distance to the object, whereas the direct ToF sensor directly measures the flight time from when the irradiation light is emitted to when the reflected light is received and calculates the distance to the object.

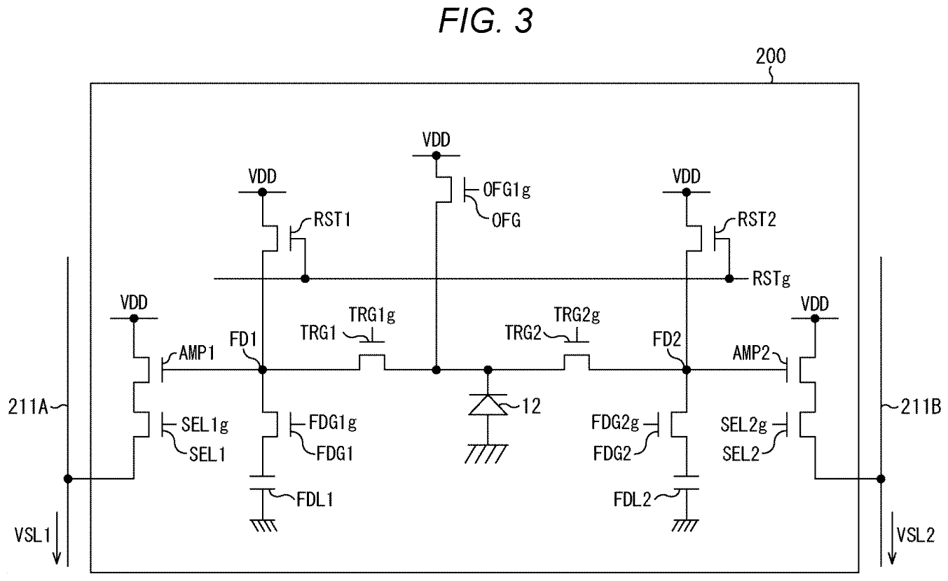

FIG. 3 illustrates a pixel circuit example in a case where the photodetection device 1 is a gate type ToF sensor.

The gate type ToF sensor is an indirect ToF sensor that detects a phase difference by distributing charges generated by the photodiode 12 by two transfer gates (transfer transistors) and calculates the distance to the object.

A pixel 200 includes the photodiode 12 as the photoelectric conversion section. Furthermore, the pixel 200 includes two transfer transistors TRG, two floating diffusion regions FD, two additional capacitors FDL, two switching transistors FDG, two amplification transistors AMP, two reset transistors RST, and two selection transistors SEL. Moreover, the pixel 200 includes a charge discharge transistor OFG.

Here, in a case where each two pieces of the transfer transistor TRG, the floating diffusion region FD, the additional capacitor FDL, the switching transistor FDG, the amplification transistor AMP, the reset transistor RST, and the selection transistor SEL provided two by two in the pixel 200 are distinguished from each other, as illustrated in FIG. 3, they are referred to as the transfer transistors TRG1 and TRG2, the floating diffusion regions FD1 and FD2, the additional capacitors FDL1 and FDL2, the switching transistors FDG1 and FDG2, the amplification transistors AMP1 and AMP2, the reset transistors RST1 and RST2, and the selection transistors SEL1 and SEL2.

The transfer transistor TRG, the switching transistor FDG, the amplification transistor AMP, the selection transistor SEL, the reset transistor RST, and the charge discharge transistor OFG each include, for example, an N-type MOS transistor.

When a transfer drive signal TRG1g supplied to a gate electrode of the transfer transistor TRG1 enters the active state, the transfer transistor TRG1 enters the conductive state in response thereto, thereby transferring the charges accumulated in the photodiode 12 to the floating diffusion region FD1. When a transfer drive signal TRG2g supplied to a gate electrode of the transfer transistor TRG2 enters the active state, the transfer transistor TRG2 enters the conductive state in response thereto, thereby transferring the charges accumulated in the photodiode 12 to the floating diffusion region FD2.

The floating diffusion regions FD1 and FD2 are charge holding sections that temporarily hold the charges transferred from the photodiode 12.

When an FD drive signal FDG1g supplied to a gate electrode of the switching transistor FDG1 enters the active state, the switching transistor FDG1 enters the conductive state in response thereto, thereby connecting the additional capacitor FDL1 to the floating diffusion region FD1. When a FD drive signal FDG2g supplied to a gate electrode of the switching transistor FDG2 enters the active state, the switching transistor FDG2 enters the conductive state in response thereto, thereby connecting the additional capacitor FDL2 to the floating diffusion region FD2. The additional capacitors FDL1 and FDL2 can be formed by, for example, wiring capacitance.

When a reset drive signal RSTg supplied to a gate electrode of the reset transistor RST1 enters the active state, the reset transistor RST1 enters the conductive state in response thereto, thereby resetting a potential of the floating diffusion region FD1. When the reset drive signal RSTg supplied to a gate electrode of the reset transistor RST2 enters the active state, the reset transistor RST2 enters the conductive state in response thereto, thereby resetting a potential of the floating diffusion region FD2. Note that, when the reset transistors RST1 and RST2 are caused to enter the active states, the switching transistors FDG1 and FDG2 are also caused to enter the active states simultaneously, and the additional capacitors FDL1 and FDL2 are also reset.

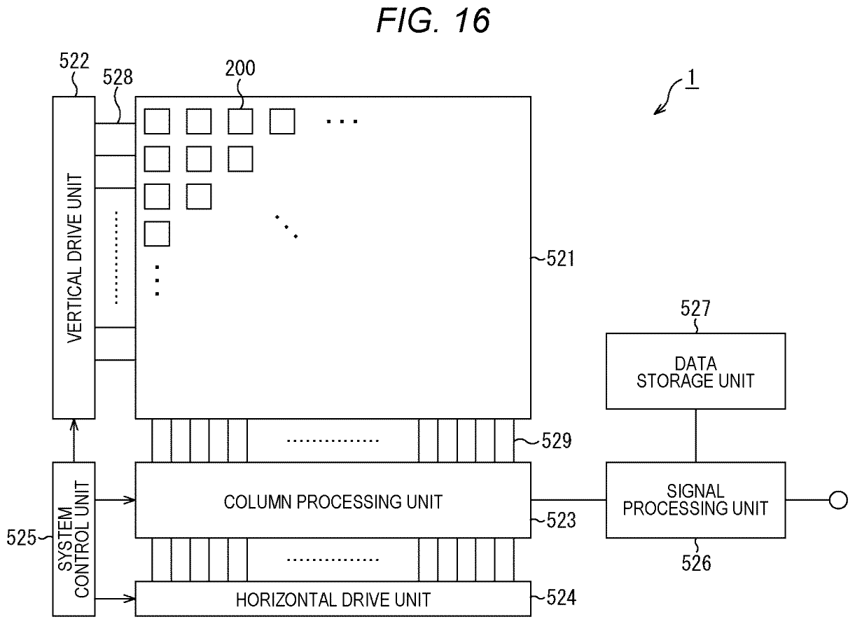

For example, at high illuminance with a large amount of incident light, a vertical drive unit (for example, a vertical drive unit 522 in FIG. 16) that drives the pixel 200 causes the switching transistors FDG1 and FDG2 to enter the active states, connects the floating diffusion region FD1 and the additional capacitor FDL1 together, and connects the floating diffusion region FD2 and the additional capacitor FDL2 together. As a result, it is possible to accumulate more charges at the time of high illuminance.

On the other hand, at low illuminance with a small amount of incident light, the vertical drive unit causes the switching transistors FDG1 and FDG2 to enter the inactive state, and separates the additional capacitors FDL1 and FDL2 from the floating diffusion regions FD1 and FD2, respectively. As a result, it is possible to increase conversion efficiency.

When a discharge drive signal OFG1g supplied to a gate electrode of the charge discharge transistor OFG enters the active state, the charge discharge transistor OFG enters the conductive state in response thereto, thereby discharging the charges accumulated in the photodiode 12.

A source electrode of the amplification transistor AMP1 is connected to a vertical signal line 211A via the selection transistor SEL1, whereby the amplification transistor AMP1 is connected to a constant current source (not depicted) to form a source follower circuit. A source electrode of the amplification transistor AMP2 is connected to a vertical signal line 211B via the selection transistor SEL2, whereby the amplification transistor AMP2 is connected to a constant current source (not depicted) to form a source follower circuit.

The selection transistor SEL1 is connected between the source electrode of the amplification transistor AMP1 and the vertical signal line 211A. When a selection drive signal SEL1g supplied to a gate electrode of the selection transistor SEL1 enters the active state, the selection transistor SEL1 enters the conductive state in response thereto, and outputs a pixel signal VSL1 output from the amplification transistor AMP1 to the vertical signal line 211A.

The selection transistor SEL2 is connected between the source electrode of the amplification transistor AMP2 and the vertical signal line 211B. When a selection drive signal SEL2g supplied to a gate electrode of the selection transistor SEL2 enters the active state, the selection transistor SEL2 enters the conductive state in response thereto, and outputs a pixel signal VSL2 output from the amplification transistor AMP2 to the vertical signal line 211B.

The transfer transistors TRG1 and TRG2, the switching transistors FDG1 and FDG2, the amplification transistors AMP1 and AMP2, the selection transistors SEL1 and SEL2, and the charge discharge transistor OFG of the pixel 200 are controlled by the vertical drive unit.

In the pixel circuit of FIG. 3, the additional capacitors FDL1 and FDL2 and the switching transistors FDG1 and FDG2 that control connection thereof may be omitted, but it is possible to secure a high dynamic range by providing the additional capacitors FDL and selectively using them according to the amount of incident light.

Operation of the pixel 200 of FIG. 3 will be briefly described.

First, before light reception is started, reset operation of resetting charges of the pixel 200 is performed in all the pixels of the pixel array unit in which the pixels 200 are arranged in a matrix. That is, the charge discharge transistor OFG, the reset transistors RST1 and RST2, and the switching transistors FDG1 and FDG2 are turned on, and the accumulated charges of the photodiode 12, the floating diffusion regions FD1 and FD2, and the additional capacitors FDL1 and FDL2 are discharged.

After the accumulated charges are discharged, the light reception is started in all the pixels. In a light receiving period, the transfer transistors TRG1 and TRG2 are alternately driven. That is, in a first period, the transfer transistor TRG1 is controlled to be turned on, and the transfer transistor TRG2 is controlled to be turned off. In the first period, the charges generated in the photodiode 12 are transferred to the floating diffusion region FD1. In a second period next to the first period, the transfer transistor TRG1 is controlled to be turned off, and the transfer transistor TRG2 is controlled to be turned on. In the second period, the charges generated in the photodiode 12 are transferred to the floating diffusion region FD2. As a result, the charges generated in the photodiode 12 are alternately distributed and accumulated in the floating diffusion regions FD1 and FD2.

Then, when the light receiving period ends, the pixels 200 of the pixel array unit are selected sequentially by line. In the selected pixels 200, the selection transistors SEL1 and SEL2 are turned on. As a result, the charges accumulated in the floating diffusion region FD1 are output as the pixel signal VSL1 via the vertical signal line 211A. The charges accumulated in the floating diffusion region FD2 are output as the pixel signal VSL2 via the vertical signal line 211B.

As described above, one time of light receiving operation ends, and the next time of light receiving operation starting from the reset operation is executed.

The reflected light received by the pixel 200 is delayed according to a distance to a target object from a timing at which a light source emits light. Since a distribution ratio of the charges accumulated in the two floating diffusion regions FD1 and FD2 changes depending on a delay time according to the distance to the target object, the distance to the object can be obtained from the distribution ratio of the charges accumulated in the two floating diffusion regions FD1 and FD2.

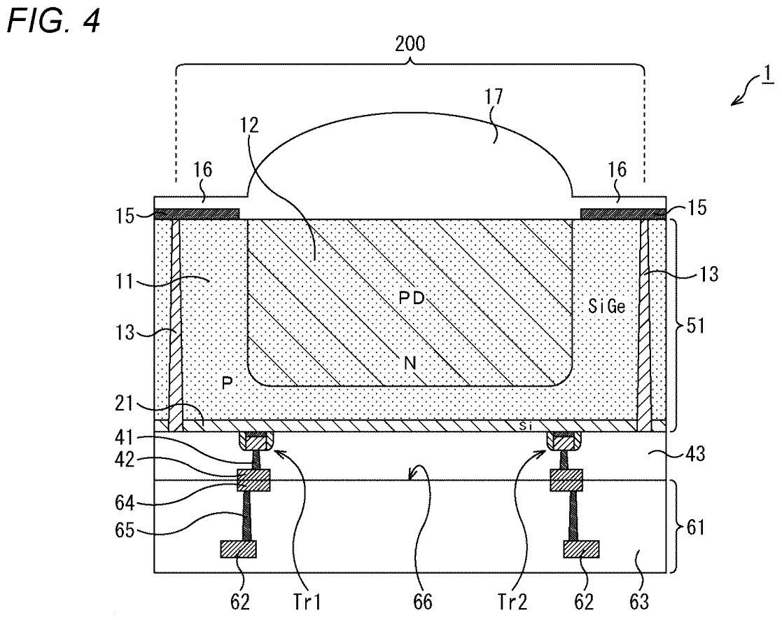

FIG. 4 is a cross-sectional view illustrating a configuration example of the pixel 200 in the case where the photodetection device 1 is the gate type ToF sensor.

In FIG. 4, portions corresponding to those in the cross-sectional view illustrated in FIG. 1 are denoted by the same reference signs, and description of the portions will be omitted as appropriate. However, reference signs of the gate insulating film 31, the gate electrode 32, and the sidewall 33 of the MOS transistor Tr are omitted.

In the case where the photodetection device 1 is the gate type ToF sensor, the photodiode 12 is formed in the SiGe layer 11 in units of the pixels 200. The element separation section 13 is formed at a boundary portion of the pixel 200, and functions as a pixel separation section that separates the photodiode 12 in units of pixels. Furthermore, the light shielding film 15 is formed at the boundary portion of the pixel 200 and functions as an inter-pixel light shielding film. The element separation section 13 illustrated in FIG. 1 has a tapered cross-sectional shape in which the trench is formed, from the back surface (upper surface in FIG. 1) side of the SiGe layer 11, so that a groove width (opening width of the trench) is narrowed from the back surface side toward the front surface side of the SiGe layer 11. On the other hand, the element separation section 13 of FIG. 4 has a reverse tapered cross-sectional shape in which the trench is formed, from the front surface side of the SiGe layer 11, so that the groove width (opening width of the trench) is narrowed from the front surface side toward the back surface side of the SiGe layer 11.

Two MOS transistors Tr1 and Tr2 are formed on the MOS transistor formation surface on which the Si layer 21 is formed. The two MOS transistors Tr1 and Tr2 correspond to the transfer transistors TRG1 and TRG2 of the pixel circuit of FIG. 3. The switching transistors FDG1 and FDG2, the amplification transistors AMP1 and AMP2, the selection transistors SEL1 and SEL2, the reset transistors RST1 and RST2, and the charge discharge transistor OFG, which are the other pixel transistors of the pixel circuit of FIG. 3, are formed on the logic substrate side (not depicted).

As described above, in a case where the photodetection device 1 is the gate type ToF sensor and the photodiode 12 of the pixel 200 is formed in the SiGe layer 11, it is possible to implement a ToF sensor having a high quantum efficiency in the infrared region and improved light receiving sensitivity.

### 4. Pixel Configuration Example in Case Where Photodetection Device is Imaging Sensor

Next, a description will be given of a pixel structure in a case where the photodetection device 1 is an IR imaging sensor that receives infrared light and generates an IR image.

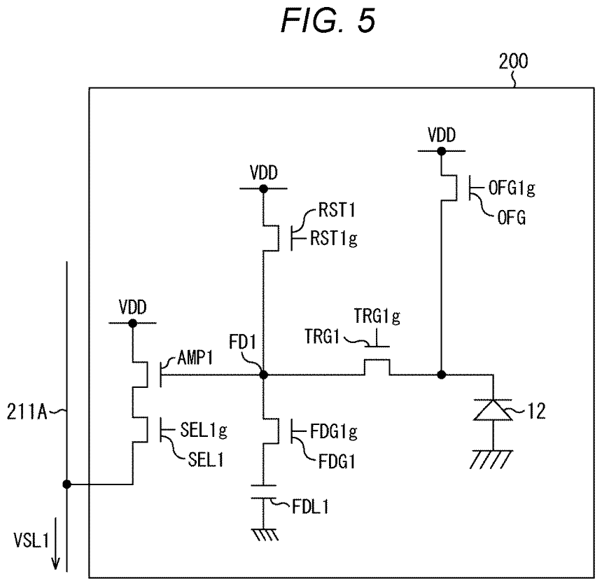

FIG. 5 illustrates a pixel circuit example in the case where the photodetection device 1 is the IR imaging sensor.

In the case where the photodetection device 1 is the above-described gate type ToF sensor, the charges generated in the photodiode 12 are distributed and accumulated in the two floating diffusion regions FD1 and FD2, and thus, the pixel 200 has two transfer transistors TRG, two floating diffusion regions FD, two additional capacitors FDL, two switching transistors FDG, two amplification transistors AMP, two reset transistors RST, and two selection transistors SEL.

On the other hand, in the case where the photodetection device 1 is the IR imaging sensor, the number of charge holding sections that temporarily hold the charge generated in the photodiode 12 is only required to be one, and thus, the numbers of the transfer transistors TRG, the floating diffusion regions FD, the additional capacitors FDL, the switching transistors FDG, the amplification transistors AMP, the reset transistors RST, and the selection transistors SEL each are also one.

In other words, in the case where the photodetection device 1 is the IR imaging sensor, as illustrated in FIG. 5, the pixel 200 has a configuration in which the transfer transistor TRG2, the switching transistor FDG2, the reset transistor RST2, the amplification transistor AMP2, and the selection transistor SEL2 are omitted from the circuit configuration illustrated in FIG. 3. The floating diffusion region FD2 and the vertical signal line 211B are also omitted.

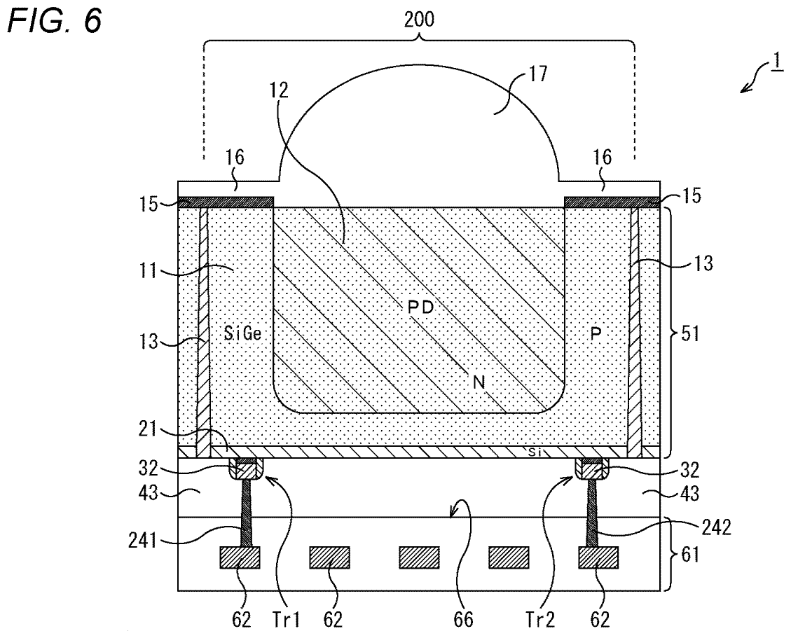

FIG. 6 is a cross-sectional view illustrating a configuration example of the pixel 200 in the case where the photodetection device 1 is the IR imaging sensor.

Also in FIG. 6, portions corresponding to those in the cross-sectional view illustrated in FIG. 1 are denoted by the same reference signs, and description of the portions will be omitted as appropriate. However, reference signs of the gate insulating film 31 and the sidewall 33 of the MOS transistor Tr are omitted.

In the case where the photodetection device 1 is the IR imaging sensor, the photodiode 12 is formed in the SiGe layer 11 in units of the pixels 200. The element separation section 13 is formed at the boundary portion of the pixel 200, and functions as a pixel separation section that separates the photodiode 12 in units of pixels. Furthermore, the light shielding film 15 is formed at the boundary portion of the pixel 200 and functions as the inter-pixel light shielding film. Also in FIG. 6, similarly to the case of the gate type ToF sensor illustrated in FIG. 4, the element separation section 13 has a reverse tapered cross-sectional shape in which the trench is formed, from the front surface side of the SiGe layer 11, so that the groove width is narrowed from the front surface side to the back surface side of the SiGe layer 11.

Two MOS transistors Tr1 and Tr2 are formed on the MOS transistor formation surface on which the Si layer 21 is formed. The two MOS transistors Tr1 and Tr2 correspond to, for example, the transfer transistor TRG1 and the charge discharge transistor OFG of the pixel circuit of FIG. 5. The switching transistor FDG1, the amplification transistor AMP1, the selection transistor SEL1, and the reset transistor RST1, which are the other pixel transistors of the pixel circuit of FIG. 3, are formed on the logic substrate side (not depicted).

Furthermore, in the cross-sectional view illustrated in FIG. 1, the bonding electrodes 42 and 64 are formed on the bonding surface 66 between the wiring layer 61 and the insulating layer 43, and a voltage applied to the gate electrode 32 of the MOS transistor Tr is supplied via the bonding electrodes 42 and 64. On the other hand, in the cross-sectional view of the pixel 200 of FIG. 6, the bonding electrodes 42 and 64 are omitted in the bonding surface 66, and the gate electrode 32 of the MOS transistor Tr1 is connected to a predetermined metal wiring line 62 of the wiring layer 61 via a contact electrode 241. Similarly, the gate electrode 32 of the MOS transistor Tr2 is connected to a predetermined metal wiring line 62 of the wiring layer 61 via a contact electrode 242. As described above, voltages applied to the gate electrodes 32 of the MOS transistors Tr1 and Tr2 may be supplied only by vias (through electrodes) without passing through the bonding electrodes 42 and 64. Of course, as in FIGS. 1 and 4, the applied voltage may be supplied via the bonding electrodes 42 and 64.

Note that the photodetection device 1 may be an RGBIR imaging sensor that receives infrared light and RGB light. In this case, a pixel arrangement of the photodetection device 1 is only required to be a pixel arrangement in which an R pixel that receives red (R) light, a G pixel that receives green (G) light, a B pixel that receives blue (B) light, and an IR pixel that receives infrared (IR) light are allocated to four pixels of 2×2, and repeatedly arranged in a matrix. Whether each pixel 200 is the R pixel, the B pixel, the G pixel, or the IR pixel can be controlled by, for example, insertion of a color filter layer between the photodiode 12 and the on-chip lens 17.

### 5. Pixel Configuration Example in Case Where Photodetection Device is CAPD Type ToF Sensor

Next, a description will be given of a pixel structure in a case where the photodetection device 1 is a current assisted photonic demodulator (CAPD) type ToF sensor.

The CAPD type ToF sensor is an indirect ToF sensor of a type in which a voltage is directly applied to the semiconductor substrate 51 to generate a current in the substrate, and a photoelectric conversion region in a wide range in the substrate is modulated at a high speed to distribute a photoelectrically converted charges.

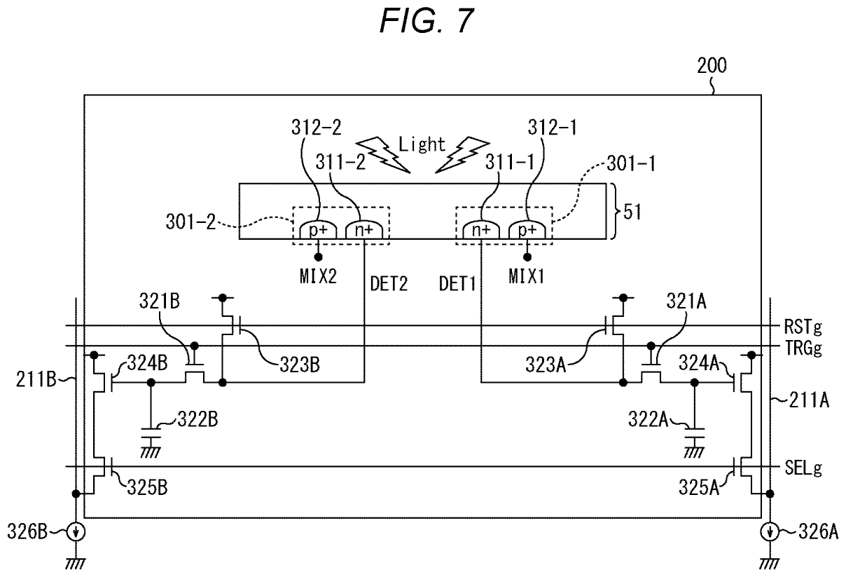

FIG. 7 illustrates a pixel circuit example in the case where the photodetection device 1 is the CAPD type ToF sensor.

The pixel 200 of FIG. 7 includes signal extraction sections 301-1 and 301-2 in the semiconductor substrate 51. The signal extraction section 301-1 includes at least an N+ semiconductor region 311-1 that is an N-type semiconductor region and a P+ semiconductor region 312-1 that is a P-type semiconductor region. The signal extraction section 301-2 includes at least an N+ semiconductor region 311-2 that is an N-type semiconductor region and a P+ semiconductor region 312-2 that is a P-type semiconductor region.

The pixel 200 includes a transfer transistor 321A, an FD 322A, a reset transistor 323A, an amplification transistor 324A, and a selection transistor 325A with respect to the signal extraction section 301-1.

Furthermore, the pixel 200 includes a transfer transistor 321B, an FD 322B, a reset transistor 323B, an amplification transistor 324B, and a selection transistor 325B with respect to the signal extraction section 301-2.

The vertical drive unit applies a predetermined voltage MIX1 (first voltage) to the P+ semiconductor region 312-1 and applies a predetermined voltage MIX2 (second voltage) to the P+ semiconductor region 312-2. For example, one of the voltages MIX1 and MIX2 is 1.5 V, and the other is 0 V. The P+ semiconductor regions 312-1 and 312-2 are voltage application sections to which the first voltage or the second voltage is applied.

The N+ semiconductor regions 311-1 and 311-2 are charge detection sections that detect and accumulate charges generated by photoelectric conversion of light incident on the semiconductor substrate 51.

When a transfer drive signal TRGg supplied to a gate electrode of the transfer transistor 321A enters the active state, the transfer transistor 321A enters the conductive state in response thereto, thereby transferring the charges accumulated in the N+ semiconductor region 311-1 to the FD 322A. When the transfer drive signal TRGg supplied to a gate electrode of the transfer transistor 321B enters the active state, the transfer transistor 321B enters the conductive state in response thereto, thereby transferring the charges accumulated in the N+ semiconductor region 311-2 to the FD 322B.

The FD 322A temporarily holds the charges supplied from the N+ semiconductor region 311-1. The FD 322B temporarily holds the charges supplied from the N+ semiconductor region 311-2.

When the reset drive signal RSTg supplied to a gate electrode of the reset transistor 323A enters the active state, the reset transistor 323A enters the conductive state in response thereto, thereby resetting a potential of the FD 322A to a predetermined level (reset voltage VDD). When the reset drive signal RSTg supplied to a gate electrode of the reset transistor 323B enters the active state, the reset transistor 323B enters the conductive state in response thereto, thereby resetting a potential of the FD 322B to the predetermined level (reset voltage VDD). Note that when the reset transistors 323A and 323B are caused to enter the active states, the transfer transistors 321A and 321B are also caused to enter the active states simultaneously.

A source electrode of the amplification transistor 324A is connected to the vertical signal line 211A via the selection transistor 325A, whereby a source follower circuit is formed with a load MOS of a constant current source circuit section 326A connected to one end of the vertical signal line 211A. A source electrode of the amplification transistor 324B is connected to the vertical signal line 211B via the selection transistor 325B, whereby a source follower circuit is formed with a load MOS of a constant current source circuit section 326B connected to one end of the vertical signal line 211B.

The selection transistor 325A is connected between the source electrode of the amplification transistor 324A and the vertical signal line 211A. When a selection drive signal SELg supplied to a gate electrode of the selection transistor 325A enters the active state, the selection transistor 325A enters the conductive state in response thereto, and outputs a pixel signal output from the amplification transistor 324A to the vertical signal line 211A.

The selection transistor 325B is connected between the source electrode of the amplification transistor 324B and the vertical signal line 211B. When the selection drive signal SELg supplied to a gate electrode of the selection transistor 325B enters the active state, the selection transistor 325B enters the conductive in response thereto, and outputs a pixel signal output from the amplification transistor 324B to the vertical signal line 211B.

The transfer transistors 321A and 321B, the reset transistors 323A and 323B, the amplification transistors 324A and 324B, and the selection transistors 325A and 325B of the pixel 200 are controlled by, for example, the vertical drive unit that drives the pixel 200.

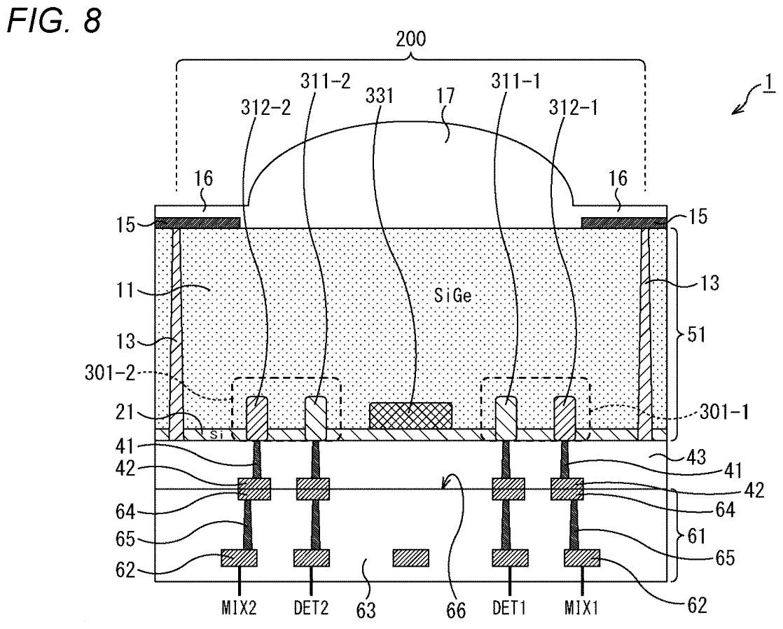

FIG. 8 is a cross-sectional view illustrating a configuration example of the pixel 200 in the case where the photodetection device 1 is the CAPD type ToF sensor.

Also in FIG. 8, portions corresponding to those in the cross-sectional view illustrated in FIG. 1 are denoted by the same reference signs, and description of the portions will be omitted as appropriate.

In the case where the photodetection device 1 is the CAPD type ToF sensor, the entire SiGe layer 11 of the semiconductor substrate 51 is the photoelectric conversion section. The element separation section 13 is formed at the boundary portion of the pixel 200, and functions as a pixel separation section that separates the photoelectric conversion section in units of pixels. Furthermore, the light shielding film 15 is formed at the boundary portion of the pixel 200 and functions as the inter-pixel light shielding film. Also in FIG. 8, similarly to the case of the gate type ToF sensor illustrated in FIG. 4, the element separation section 13 has a reverse tapered cross-sectional shape in which the trench is formed, from the front surface side of the SiGe layer 11, so that the groove width is narrowed from the front surface side to the back surface side of the SiGe layer 11.

In plan view, a P well 331 is formed in the center portion of the pixel 200 and in the vicinity of an interface on the front surface side of the SiGe layer 11, and the signal extraction section 301-1 and the signal extraction section 301-2 are formed so as to sandwich the P well 331 therebetween.

The signal extraction section 301-1 includes at least the N+ semiconductor region 311-1 and the P+ semiconductor region 312-1. The signal extraction section 301-2 includes at least the N+ semiconductor region 311-2 and the P+ semiconductor region 312-2.

The predetermined voltage MIX1 is applied to the P+ semiconductor region 312-1 of the signal extraction section 301-1 from the logic substrate side via a predetermined metal wiring line 62, contact electrode 65, bonding electrodes 64 and 42, and contact electrode 41 of the wiring layer 61.

In the N+ semiconductor region 311-1 of the signal extraction section 301-1, a signal DET1 corresponding to charges obtained by photoelectric conversion is output to a metal wiring line 62 on the logic substrate side via a predetermined contact electrode 41, bonding electrodes 42 and 64, and contact electrode 65.

The predetermined voltage MIX2 is applied to the P+ semiconductor region 312-2 of the signal extraction section 301-2 from the logic substrate side via a predetermined metal wiring line 62, contact electrode 65, bonding electrodes 64 and 42, and contact electrode 41 of the wiring layer 61.

In the N+ semiconductor region 311-2 of the signal extraction section 301-2, a signal DET2 corresponding to charges obtained by photoelectric conversion is output to a metal wiring line 62 on the logic substrate side via a predetermined contact electrode 41, bonding electrodes 42 and 64, and contact electrode 65.

Operation of the pixel 200 of FIG. 8 will be described.

The vertical drive unit drives the pixel 200 and distributes a signal corresponding to the charges obtained by photoelectric conversion to the FD 322A and the FD 322B (FIG. 7).

The vertical drive unit applies a voltage to the two P+ semiconductor regions 312. For example, the vertical drive unit applies a voltage of 1.5 V to the P+ semiconductor region 312-1 and applies a voltage of 0 V to the P+ semiconductor region 312-2.

By the application of the voltage, an electric field is generated between the two P+ semiconductor regions 312 in the SiGe layer 11, and a current flows from the P+ semiconductor region 312-1 to the P+ semiconductor region 312-2. In this case, holes (holes) in the SiGe layer 11 move in a direction of the P+ semiconductor region 312-2, and electrons move in a direction of the P+ semiconductor region 312-1.

Thus, in such a state, when infrared light (reflected light) from the outside is incident into the SiGe layer 11 via the on-chip lens 17, and the infrared light is photoelectrically converted in the SiGe layer 11 and converted into pairs of electrons and holes, the obtained electrons are guided in the direction of the P+ semiconductor region 312-1 by the electric field between the P+ semiconductor regions 312, and move into the N+ semiconductor region 311-1.

In this case, the electrons generated by photoelectric conversion are used as signal charges for detecting a signal corresponding to an amount of infrared light incident on the pixel 200, that is, a received light amount of the infrared light.

As a result, in the N+ semiconductor region 311-1, charges corresponding to electrons moving into the N+ semiconductor region 311-1 are accumulated, and the signal DET1 corresponding to the charges is output via the FD 322A, the amplification transistor 324A, the vertical signal line 211A, and the like.

That is, the accumulated charges in the N+ semiconductor region 311-1 are transferred to the FD 322A directly connected to the N+ semiconductor region 311-1, and the signal DET1 corresponding to the charges transferred to the FD 322A is read out via the amplification transistor 324A and the vertical signal line 211A.

The pixel signal is a signal indicating an amount of charges corresponding to the electrons detected by the N+ semiconductor region 311-1, that is, an amount of charges accumulated in the FD 322A. In other words, it can also be said that the pixel signal is a signal indicating a light amount of infrared light received by the pixel 200.

Note that, at this time, similarly to the case of the N+ semiconductor region 311-1, the pixel signal corresponding to electrons detected by the N+ semiconductor region 311-2 may also be appropriately used for distance measurement.

Furthermore, at the next timing, a voltage is applied to the two P+ semiconductor regions 312 by the vertical drive unit so as to generate an electric field in a direction opposite to the electric field generated in the SiGe layer 11 so far. Specifically, for example, the voltage of 1.5 V is applied to the P+ semiconductor region 312-2, and the voltage of 0 V is applied to the P+ semiconductor region 312-1.

As a result, an electric field is generated between the two P+ semiconductor regions 312 in the SiGe layer 11, and a current flows from the P+ semiconductor region 312-2 to the P+ semiconductor region 312-1.

In such a state, when infrared light (reflected light) from the outside is incident into the SiGe layer 11 via the on-chip lens 17, and the infrared light is photoelectrically converted in the SiGe layer 11 and converted into pairs of electrons and holes, the obtained electrons are guided in the direction of the P+ semiconductor region 312-2 by the electric field between the P+ semiconductor regions 312, and move into the N+ semiconductor region 311-2.

As a result, in the N+ semiconductor region 311-2, charges corresponding to electrons moving into the N+ semiconductor region 311-2 are accumulated, and the charges are output via the FD 322B, the amplification transistor 324B, the vertical signal line 211B, and the like.

That is, the accumulated charges in the N+ semiconductor region 311-2 are transferred to the FD 322B directly connected to the N+ semiconductor region 311-2, and the signal DET2 corresponding to the charges transferred to the FD 322B is read out via the amplification transistor 324B and the vertical signal line 211B.

Note that, at this time, similarly to the case of the N+ semiconductor region 311-2, the pixel signal corresponding to the electrons detected by the N+ semiconductor region 311-1 may also be appropriately used for distance measurement.

In this manner, when pixel signals obtained by photoelectric conversion in periods different from each other are obtained in the same pixel 200, the distance to the target object can be calculated on the basis of the pixel signals.

In the configuration of the pixel 200 of the CAPD type ToF sensor, as illustrated in FIG. 8, the MOS transistor Tr is not formed on the front surface of the SiGe layer 11. Therefore, in the example of FIG. 8, the Si layer 21 is formed on the front surface of the SiGe layer 11 similarly to the above-described other cross-sectional configurations, but the Si layer 21 can be omitted. Since it is not necessary to form the Si layer 21, a manufacturing process becomes easy.

### 6. Pixel Configuration Example in Case Where Photodetection Device is Direct ToF Sensor Using SPAD

Next, a description will be given of a pixel structure in a case where the photodetection device 1 is a direct ToF sensor using a single photon avalanche diode (SPAD).

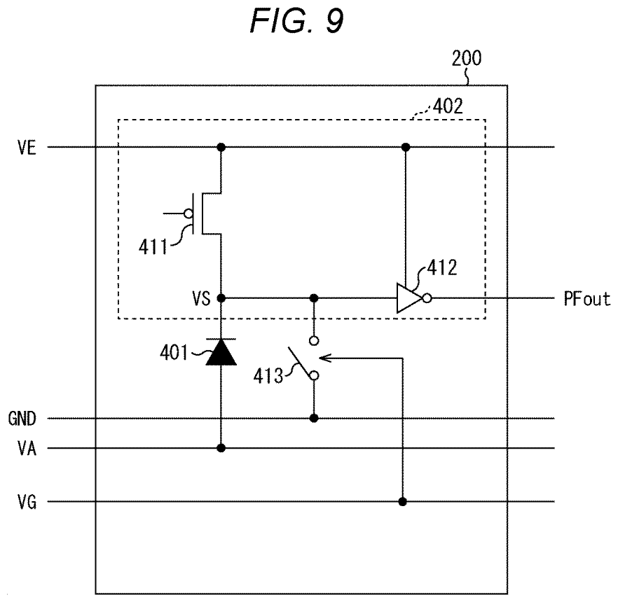

FIG. 9 illustrates a pixel circuit example in the case where the photodetection device 1 is the direct ToF sensor using the SPAD.

The pixel 200 in FIG. 9 includes a SPAD 401 and a readout circuit 402 including a transistor 411 and an inverter 412. Furthermore, the pixel 200 also includes a switch 413. The transistor 411 includes a P-type MOS transistor.

The cathode of the SPAD 401 is connected to the drain of the transistor 411, and is connected to an input terminal of the inverter 412 and one end of the switch 413. The anode of the SPAD 401 is connected to a power supply voltage VA (Hereinafter, the power supply voltage VA is also referred to as an anode voltage VA.).

The SPAD 401 is a photodiode (single photon avalanche photodiode) that performs avalanche amplification of generated electrons and outputs a signal of a cathode voltage VS when incident light is incident. The power supply voltage VA supplied to the anode of the SPAD 401 is, for example, a negative bias (negative potential) of about −20 V.

The transistor 411 is a constant current source that operates in a saturation region, and performs passive quenching by acting as a quenching resistor. The source of the transistor 411 is connected to a power supply voltage VE, and the drain is connected to the cathode of the SPAD 401, the input terminal of the inverter 412, and the one end of the switch 413. As a result, the power supply voltage VE is also supplied to the cathode of the SPAD 401. A pull-up resistor can also be used instead of the transistor 411 connected in series with the SPAD 401.

In order to detect light (photons) with sufficient efficiency, a voltage (excess bias (ExcessBias)) larger than a breakdown voltage VBD of the SPAD 401 is applied to the SPAD 401. For example, assuming that the breakdown voltage VBD of the SPAD 401 is 20 V and a voltage larger than that by 3 V is applied, the power supply voltage VE supplied to the source of the transistor 411 is 3 V.

Note that the breakdown voltage VBD of the SPAD 401 greatly changes depending on temperature and the like. For that reason, the applied voltage applied to the SPAD 401 is controlled (adjusted) according to the change in the breakdown voltage VBD. For example, when the power supply voltage VE is a fixed voltage, the anode voltage VA is controlled (adjusted).

The one end of both ends of the switch 413 is connected to the cathode of the SPAD 401, the input terminal of the inverter 412, and the drain of the transistor 411, and the other end is connected to the ground (GND). The switch 413 can include, for example, an N-type MOS transistor, and is turned on and off according to a gating control signal VG supplied from the vertical drive unit.

The vertical drive unit supplies the gating control signal VG of high or low to the switch 413 of each pixel 200 and turns on and off the switch 413, thereby setting each pixel 200 of the pixel array unit as an active pixel or an inactive pixel. The active pixel is a pixel that detects incidence of photons, and the inactive pixel is a pixel that does not detect incidence of photons. When the switch 413 is turned on according to the gating control signal VG and the cathode of the SPAD 401 is controlled to the ground, the pixel 200 becomes the inactive pixel.

Operation in a case where the pixel 200 in FIG. 9 is set as the active pixel will be described.

First, in a case where the pixel 200 is the active pixel, the switch 413 is set to be turned off as described above.

Since the power supply voltage VE (for example, 3 V) is supplied to the cathode of the SPAD 401 and the power supply voltage VA (for example, −20 V) is supplied to the anode, a reverse voltage larger than the breakdown voltage VBD (=20 V) is applied to the SPAD 401, so that the SPAD 401 is set to a Geiger mode.

When photons are incident on the SPAD 401 set in the Geiger mode, avalanche multiplication occurs, and a current flows through the SPAD 401. When the avalanche multiplication occurs and the current flows through the SPAD 401, the current also flows through the transistor 411 due to the current flowing through the SPAD 401, and a voltage drop occurs due to a resistance component of the transistor 411.

When the voltage drop occurs and the cathode voltage VS of the SPAD 401 becomes lower than 0 V, a state occurs in which an anode-cathode voltage of the SPAD 401 becomes lower than the breakdown voltage VBD, so that the avalanche amplification is stopped. Here, operation of stopping the avalanche amplification due to the fact that the current generated by the avalanche amplification flows through the transistor 411 to generate the voltage drop, and a state occurs in which the cathode voltage VS becomes lower than the breakdown voltage VBD due to the generated voltage drop, is quenching operation.

When the avalanche amplification is stopped, the current flowing through the resistor of the transistor 411 gradually decreases, the cathode voltage VS returns to the original power supply voltage VE again, and a state occurs in which next new photons can be detected (recharge operation).

The inverter 412 outputs a pixel signal PFout of Lo when the cathode voltage VS, which is an input voltage, is greater than or equal to a predetermined threshold voltage Vth, and outputs the pixel signal PFout of Hi when the cathode voltage VS is less than the predetermined threshold voltage Vth. Thus, when photons are incident on the SPAD 401, and avalanche multiplication occurs, and the cathode voltage VS decreases and falls below the threshold voltage Vth, the pixel signal PFout is inverted from a low level to a high level. On the other hand, when the avalanche multiplication of the SPAD 401 converges, and the cathode voltage VS rises and becomes greater than or equal to the threshold voltage Vth, the pixel signal PFout is inverted from the high level to the low level.

Note that, in a case where the pixel 200 is caused to be the inactive pixel, the switch 413 is turned on. When the switch 413 is turned on, the cathode voltage VS of the SPAD 401 becomes 0 V. As a result, since the anode-cathode voltage of the SPAD 401 becomes less than or equal to the breakdown voltage VBD, a state occurs in which no reaction occurs even if photons enter the SPAD 401.

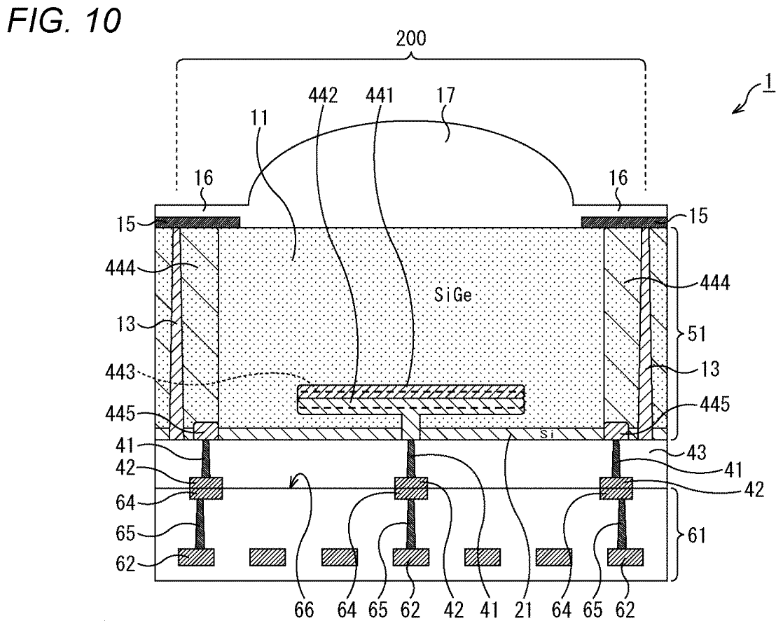

FIG. 10 is a cross-sectional view illustrating a configuration example of the pixel 200 in the case where the photodetection device 1 is the direct ToF sensor using the SPAD.

Also in FIG. 10, portions corresponding to those in the cross-sectional view illustrated in FIG. 1 are denoted by the same reference signs, and description of the portions will be omitted as appropriate.

In the case where the photodetection device 1 is the direct ToF sensor using the SPAD, the SiGe layer 11 of the semiconductor substrate 51 includes an N-well region. The element separation section 13 is formed at the boundary portion of the pixel 200, and functions as a pixel separation section that separates the photoelectric conversion section in units of pixels. Furthermore, the light shielding film 15 is formed at the boundary portion of the pixel 200 and functions as the inter-pixel light shielding film. Also in FIG. 10, similarly to the case of the gate type ToF sensor illustrated in FIG. 4, the element separation section 13 has a reverse tapered cross-sectional shape in which the trench is formed, from the front surface side of the SiGe layer 11, so that the groove width is narrowed from the front surface side to the back surface side of the SiGe layer 11.

In plan view, a P-type diffusion layer 441 and an N-type diffusion layer 442 are formed in the center portion of the pixel 200 and in the vicinity of the interface on the front surface side of the SiGe layer 11. An avalanche multiplication region 443 is formed by a depletion layer formed in a region where the P-type diffusion layer 441 and the N-type diffusion layer 442 are connected together.

A hole accumulation layer 444 is formed over the entire region from the front surface to the back surface of the SiGe layer 11 in an inner region of the element separation section 13 that is a boundary peripheral portion of the pixel 200. The hole accumulation layer 444 is connected to a high-concentration P-type diffusion layer 445 formed at the interface on the front surface side of the SiGe layer 11.

The SiGe layer 11 is controlled to be N-type by being injected with N-type impurities, and forms an electric field that transfers electrons generated by photoelectric conversion in the pixel 200 to the avalanche multiplication region 443.

The P-type diffusion layer 441 is a dense P-type diffusion layer (P+) formed over substantially the entire surface of the pixel region in the planar direction. The N-type diffusion layer 442 is a dense N-type diffusion layer (N+) formed in the vicinity of the surface of the semiconductor substrate 51 over substantially the entire surface of the pixel region, similarly to the P-type diffusion layer 441. The N-type diffusion layer 442 is a contact layer connected to the contact electrode 41 as a cathode electrode for supplying a negative voltage for forming the avalanche multiplication region 443, and a part thereof has a protruding shape formed up to the contact electrode 41 on the front surface of the semiconductor substrate 51. The power supply voltage VE is applied to the N-type diffusion layer 442 from the contact electrode 41 connected.

The hole accumulation layer 444 is a P-type diffusion layer (P) and accumulates holes. Furthermore, the hole accumulation layer 444 is connected to the high-concentration P-type diffusion layer 445 electrically connected to the contact electrode 41 as an anode electrode of the SPAD 401.

The high-concentration P-type diffusion layer 445 is a dense P-type diffusion layer (P++) formed in a peripheral portion of the pixel 200 in plan view in the vicinity of the surface of the SiGe layer 11, and forms a contact layer for electrically connecting the hole accumulation layer 444 and the contact electrode 41 of the SPAD 401 together. The power supply voltage VA is applied from the contact electrode 41 connected, to the high-concentration P-type diffusion layer 445.

The SPAD 401 as the photoelectric conversion section includes the SiGe layer 11, the P-type diffusion layer 441, the N-type diffusion layer 442, the hole accumulation layer 444, and the high-concentration P-type diffusion layer 445 of the semiconductor substrate 51, the hole accumulation layer 444 is connected to a first contact electrode 41 as the anode electrode, and the N-type diffusion layer 442 is connected to a second contact electrode 41 as the cathode electrode.

Note that the SiGe layer 11 may be controlled to be P-type by being injected with P-type impurities. In a case where the SiGe layer 11 is formed as a P-type region, a voltage applied to the N-type diffusion layer 442 is the power supply voltage VA, and a voltage applied to the high-concentration P-type diffusion layer 445 is the power supply voltage VE.

The transistor 411 and the inverter 412 forming the readout circuit 402 of the pixel 200, and the switch 413 are formed on the logic substrate side.

In the configuration of the pixel 200 of the direct ToF sensor using the SPAD, the MOS transistor Tr is not formed on the front surface of the SiGe layer 11. Therefore, in the example of FIG. 10, the Si layer 21 is formed on the front surface of the SiGe layer 11 similarly to the above-described other cross-sectional configurations, but the Si layer 21 can be omitted. Since it is not necessary to form the Si layer 21, the manufacturing process becomes easy.

### 7. Modification With Added Diffraction Structure

In the photodetection device 1 described above, a configuration is possible in which a diffraction structure for diffracting incident light is added to one or both of the back surface that is the light incident surface of the SiGe layer 11 and the front surface on the logic substrate side.

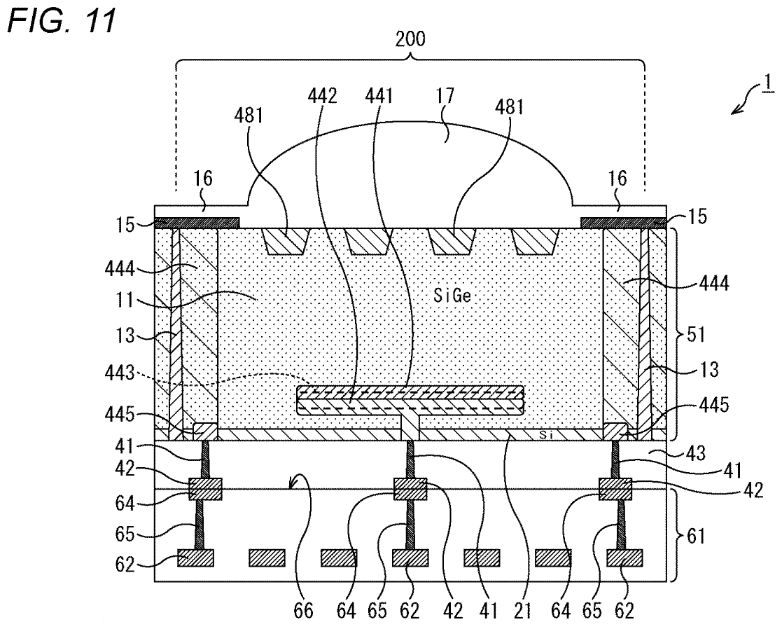

For example, FIG. 11 illustrates a cross-sectional configuration example in which the diffraction structure is added to the pixel 200 of the direct ToF sensor illustrated in FIG. 10. The pixel 200 in FIG. 11 is provided with a diffraction structure 481 in which a recess is formed at a predetermined depth at a light incident surface side interface of the SiGe layer 11 and a silicon oxide film as an insulating film is embedded in the recess. The diffraction structure 481 can be formed as shallow trench isolation (STI) by using isotropic dry etching, for example.

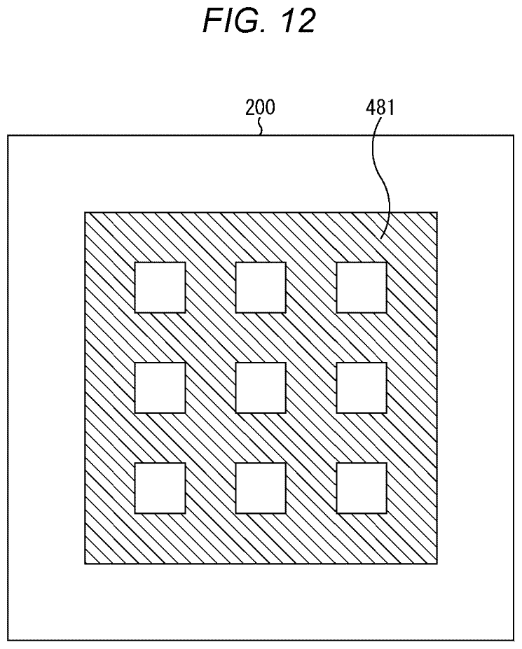

FIG. 12 is a plan view illustrating a planar shape of the diffraction structure 481 of FIG. 11. The diffraction structure 481 can be formed in a planar shape of a 4×4 lattice pattern, for example, as illustrated in FIG. 12. Note that, as a matter of course, the planar shape of the diffraction structure 481 is not limited to the 4×4 lattice pattern, and may be other shapes.

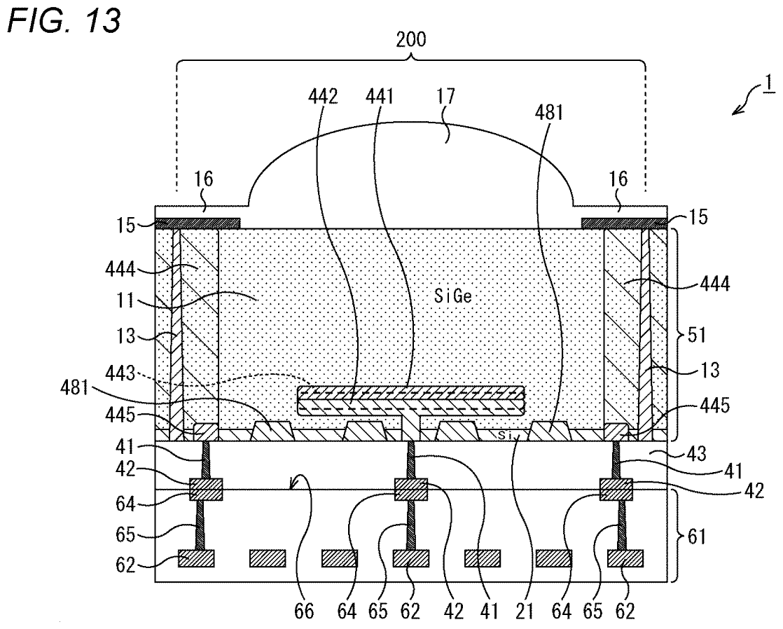

FIG. 13 illustrates a cross-sectional configuration example in which the same diffraction structure 481 as in FIG. 11 is added to the front surface side of the SiGe layer 11 of the pixel 200 of the direct ToF sensor illustrated in FIG. 10.

In the pixel 200 in FIGS. 11 and 13, the configuration other than the diffraction structure 481 is similar to that of the pixel 200 illustrated in FIG. 10, and thus the description thereof will be omitted.

By providing the diffraction structure 481 on the back surface or the front surface of the SiGe layer 11, it is possible to increase an optical path length by a light scattering effect, and improve the light receiving sensitivity. Although FIGS. 11 to 13 illustrate examples in which the diffraction structure 481 is added to the pixel structure of the direct ToF sensor illustrated in FIG. 10, it goes without saying that the diffraction structure 481 may be added to the pixel structure of the gate type ToF sensor illustrated in FIG. 4, the IR imaging sensor illustrated in FIG. 6, and the CAPD type ToF sensor illustrated in FIG. 8.

### 8. Modification of Element Separation Section

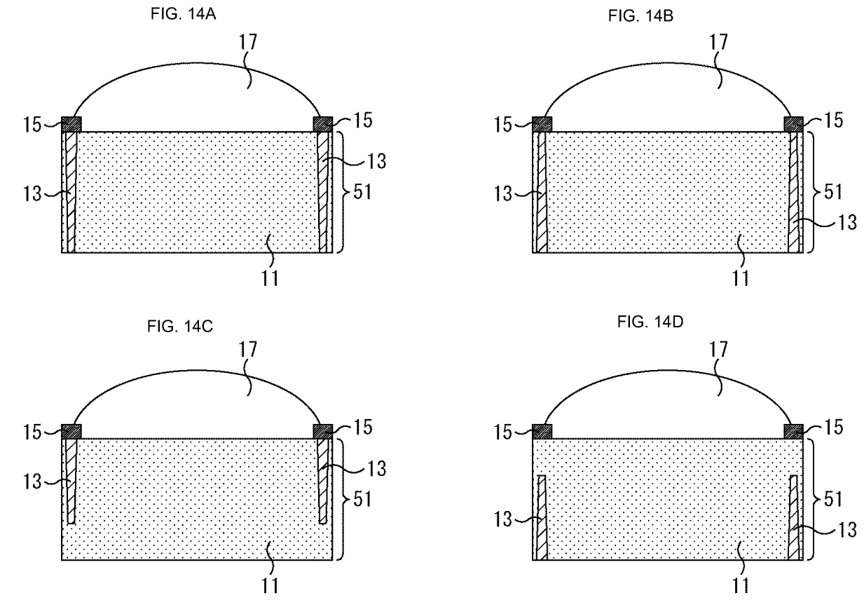

FIG. 14 is a diagram illustrating a modification of the element separation section 13 (pixel separation section) in the photodetection device 1.

For the element separation section 13, in the cross-sectional structure of each of the photodetection devices 1 described above, a cross-sectional shape has been adopted, which is a tapered cross-sectional shape in which the trench penetrates the SiGe layer 11 and the groove width is narrowed from the back surface side of the SiGe layer 11 toward the front surface side as in A of FIG. 14, or a reverse tapered cross-sectional shape in which the groove width is narrowed from the front surface side of the SiGe layer 11 toward the back surface side as in B of FIG. 14.

However, the element separation section 13 may have a structure that does not penetrate the SiGe layer 11 and is formed in a part in the depth direction.

C of FIG. 14 illustrates an example in which the element separation section 13 is formed to a depth in the middle of the SiGe layer 11 by a method for forming a trench from the back surface (upper surface in FIG. 14) side of the SiGe layer 11.

D of FIG. 14 illustrates an example in which the element separation section 13 is formed to a depth in the middle of the SiGe layer 11 by a method for forming a trench from the front surface (lower surface in FIG. 14) side of the SiGe layer 11.

Moreover, in FIGS. 11 to 13 described above, an example has been described in which the pixel 200 has the diffraction structure 481 by STI or the like, but the diffraction structure of the pixel 200 may be formed by using the same method as the method for forming the trench of the element separation section 13.

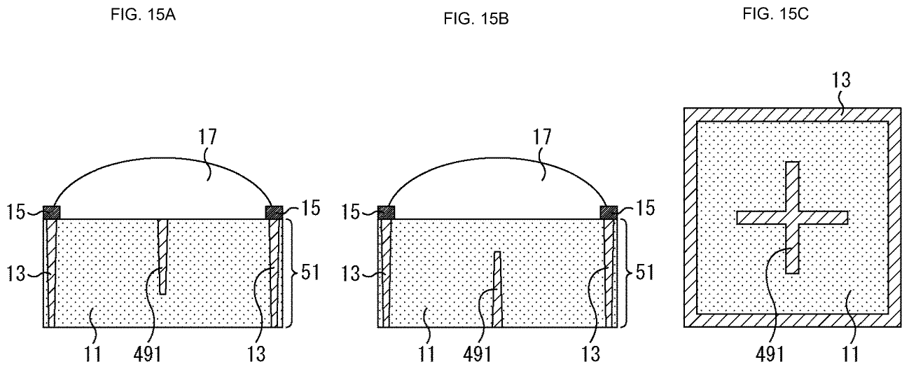

A of FIG. 15 illustrates an example in which a diffraction structure 491 is provided in a region near the center of the pixel 200 by using a method for forming a trench from the back surface side of the SiGe layer 11.

B of FIG. 15 illustrates an example in which the diffraction structure 491 is provided in a region near the center of the pixel 200 by using a method for forming a trench from the front surface side of the SiGe layer 11. In the diffraction structure 491 formed by using the same method as the method for forming the trench of the element separation section 13, a depth of the trench can be formed deeper than the diffraction structure 481 illustrated in FIGS. 11 to 13.

C of FIG. 15 is a plan view illustrating a planar shape of the diffraction structure 491. For example, as illustrated in C of FIG. 15, the diffraction structure 491 can be formed in a cross-shaped planar shape intersecting at a pixel central portion. Note that, as a matter of course, the planar shape of the diffraction structure 491 is not limited to the cross-shaped planar shape, and may be a lattice pattern as that of the diffraction structure 481 or other shapes.

### 9. Configuration Example of Photodetection Device

FIG. 16 is a block diagram illustrating a schematic configuration example of the photodetection device 1 including the pixel 200 described above.

The photodetection device 1 illustrated in FIG. 16 includes a pixel array unit 521 in which the above-described pixels 200 are arranged in a matrix in the row direction and the column direction, and a peripheral circuit unit. The peripheral circuit unit includes, for example, a vertical drive unit 522, a column processing unit 523, a horizontal drive unit 524, a system control unit 525, and the like.

The photodetection device 1 is further provided with a signal processing unit 526 and a data storage unit 527. Note that the signal processing unit 526 and the data storage unit 527 may be mounted on the same substrate as the photodetection device 1, or may be arranged on a substrate in a module different from the photodetection device 1.

The pixel array unit 521 has a configuration in which the pixels 200 that generate charges corresponding to amounts of received light and output signals corresponding to the charges are arranged in a matrix in the row direction and the column direction. Here, the row direction refers to an arrangement direction of the pixels 200 in the horizontal direction, and the column direction refers to an arrangement direction of the pixels 200 in the vertical direction. The row direction is the lateral direction in the figure, and the column direction is the longitudinal direction in the figure. Thus, the pixel array unit 521 includes the plurality of pixels 200 that performs photoelectric conversion on light incident thereon and outputs a signal corresponding to charges obtained as a result thereof. In a case where the pixel 200 has the configuration described with reference to FIGS. 3 and 4, the photodetection device 1 is the gate type ToF sensor, and in a case where the pixel has the configuration described with reference to FIGS. 5 and 6, the photodetection device 1 is the IR imaging sensor. Furthermore, in a case where the pixel 200 has the configuration described with reference to FIGS. 7 and 8, the photodetection device 1 is the CAPD type ToF sensor, and in a case where the pixel has the configuration described with reference to FIGS. 9 and 10, the photodetection device 1 is the direct ToF sensor using the SPAD.

In the pixel array unit 521, a pixel drive line 528 is wired along the row direction for each pixel row and a vertical signal line 529 is wired along the column direction of the pixels with respect to the pixel arrangement in a matrix. For example, the pixel drive line 528 transmits a drive signal for performing driving when a signal is read from the pixel 200. Note that, in FIG. 16, the pixel drive line 528 is illustrated as one wiring line, but is not limited to one. One end of the pixel drive line 528 is connected to one of output terminals corresponding to respective rows of the vertical drive unit 522. The vertical signal line 529 corresponds to the vertical signal lines 211A and 211B described in FIG. 3 and the like.

The vertical drive unit 522 includes a shift register, an address decoder, and the like, and drives the pixels 200 of the pixel array unit 521 at the same time for all the pixels, in units of rows, or the like. That is, the vertical drive unit 522 forms a control circuit that controls operation of each pixel 200 of the pixel array unit 521 together with the system control unit 525 that controls the vertical drive unit 522.

The pixel signal output from each pixel 200 of the pixel row according to drive control by the vertical drive unit 522 is input to the column processing unit 523 through the vertical signal line 529. The column processing unit 523 performs predetermined signal processing on the pixel signal output from each pixel 200 through the vertical signal line 529, and temporarily holds the pixel signal after the signal processing. Specifically, the column processing unit 523 performs noise removal processing, analog to digital (AD) conversion processing, and the like as signal processing.

The horizontal drive unit 524 includes a shift register, an address decoder, and the like, and selects unit circuits corresponding to pixel columns of the column processing unit 523 in order. By selective scanning by the horizontal drive unit 524, the pixel signals subjected to the signal processing for each unit circuit by the column processing unit 523 are output in order.

The system control unit 525 includes a timing generator that generates various timing signals, and the like, and performs drive control of the vertical drive unit 522, the column processing unit 523, the horizontal drive unit 524, and the like on the basis of the various timing signals generated by the timing generator.

The signal processing unit 526 has at least an arithmetic processing function, and performs various types of signal processing such as arithmetic processing on the basis of the pixel signal output from the column processing unit 523. In signal processing in the signal processing unit 526, the data storage unit 527 temporarily stores data necessary for the processing.

The photodetection device 1 configured as described above has a circuit configuration called a column ADC type in which AD conversion circuits for performing AD conversion processing in the column processing unit 523 are arranged for respective pixel columns.

The photodetection device 1 is a back-illuminated type device having a high quantum efficiency in the infrared region due to the fact that the photodiode 12 as a photoelectric conversion section is formed in the SiGe layer 11. The photodetection device 1 is mounted on a vehicle, for example, and can measure a distance to a target object outside a vehicle and generate a captured image. Alternatively, the photodetection device 1 is mounted on a smartphone or the like, and can measure a distance to a target object and generate a captured image.

### 10. Usage Example of Photodetection Device as Image Sensor

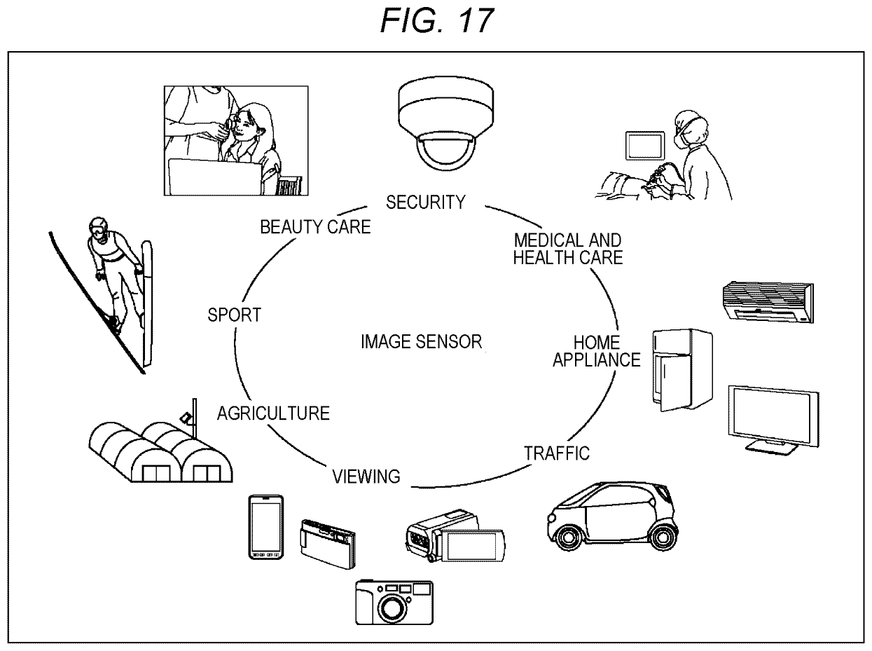

FIG. 17 is a diagram illustrating a usage example of an image sensor using the photodetection device 1 described above.

The photodetection device 1 described above can be used as an image sensor, for example, in various cases of sensing light such as infrared light, visible light, ultraviolet light, and X-rays as described below.
A device that captures an image, provided for viewing purposes, such as a digital camera and a portable device with a camera function
A device provided for traffic purposes, such as an in-vehicle sensor that captures images of the front, rear, surroundings, interior, and the like of an automobile, a monitoring camera for monitoring traveling vehicles and roads, and a ranging sensor that measures a distance between vehicles and the like, for safe driving such as automatic stop, recognition of a driver's condition, and the like
A device provided for home appliance, such as a television, a refrigerator, and an air conditioner that captures an image of a user's gesture and performs a device operation according to the gesture
A device provided for medical and health care purposes, such as an endoscope and a device that performs angiography by receiving infrared light
A device provided for security purposes, such as a monitoring camera for crime prevention and a camera for person authentication
A device provided for beauty care purposes, such as a skin measuring instrument for capturing images of skin and a microscope for capturing images of scalps
A device provided for sport purposes, such as an action camera or a wearable camera for sports applications or the like
A device provided for agricultural purposes, such as a Camera for monitoring conditions of fields and crops.

### 11. Application Example to Electronic Device

The technology of the present disclosure is not limited to application to a photodetection device. That is, the technology of the present disclosure can be applied to general electronic devices using a solid-state imaging device as an image capturing section (photoelectric conversion section), such as an imaging device such as a digital still camera or a video camera, a mobile terminal device having an imaging function, and a copying machine using a solid-state imaging device as an image reading unit. The solid-state imaging device may be formed as one chip, or may be in a module form having an imaging function in which an image pickup unit and a signal processing unit or an optical system are packaged together.

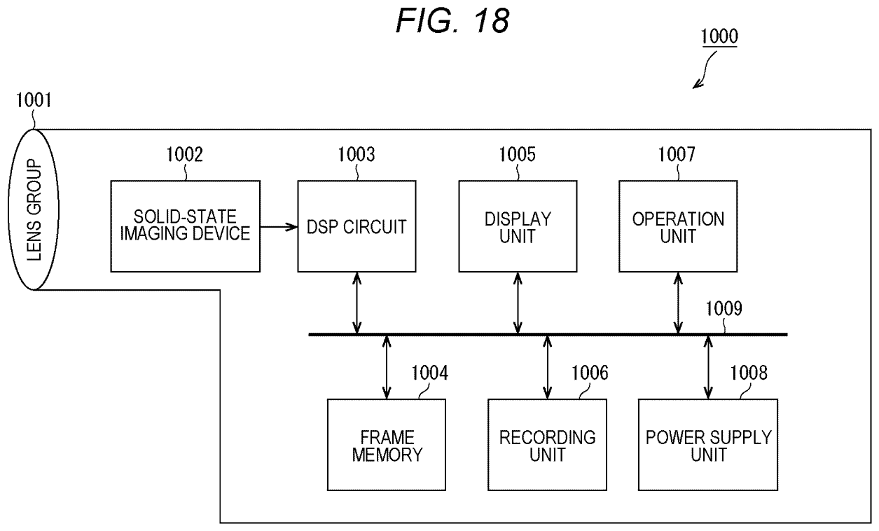

FIG. 18 is a block diagram illustrating a configuration example of an imaging device as an electronic device to which the technology of the present disclosure is applied.

An imaging device 1000 in FIG. 18 includes an optical unit 1001 including a lens group and the like, a solid-state imaging device (imaging device) 1002 that adopts the configuration of the photodetection device 1 in FIG. 1, and a digital signal processor (DSP) circuit 1003 that is a camera signal processing circuit. Furthermore, the imaging device 1000 also includes a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected to one another via a bus line 1009.

The optical unit 1001 captures incident light (image light) from a subject and forms an image on an imaging surface of the solid-state imaging device 1002. The solid-state imaging device 1002 converts the light amount of the incident light imaged on the imaging surface by the optical unit 1001 into an electric signal for each pixel and outputs the electric signal as a pixel signal. As the solid-state imaging device 1002, it is possible to use the photodetection device 1 of FIG. 1, that is, a photodetection device having a high quantum efficiency in the infrared region and improved sensitivity to light in the infrared region.

The display unit 1005 includes, for example, a thin display such as a liquid crystal display (LCD) or an organic electro luminescence (EL) display, and displays a moving image or a still image captured by the solid-state imaging device 1002. The recording unit 1006 records the moving image or the still image captured by the solid-state imaging device 1002 on a recording medium such as a hard disk or a semiconductor memory.

The operation unit 1007 issues operation commands regarding various functions of the imaging device 1000 under operation by a user. The power supply unit 1008 appropriately supplies various kinds of power that are the operating power supplies for the DSP circuit 1003, the frame memory 1004, the display unit 1005, the recording unit 1006, and the operation unit 1007, to these supply targets.

As described above, by using the photodetection device 1 described above as the solid-state imaging device 1002, it is possible to improve the sensitivity to light in the infrared region. Thus, also in the imaging device 1000 such as a video camera, a digital still camera, or a camera module for a mobile device such as a mobile phone, the image quality of the captured image can be improved.

### 12. Application Example to Endoscopic Surgery System

The technology according to the present disclosure (present technology) can be applied to various products. For example, the technology according to the present disclosure may be applied to an endoscopic surgery system.

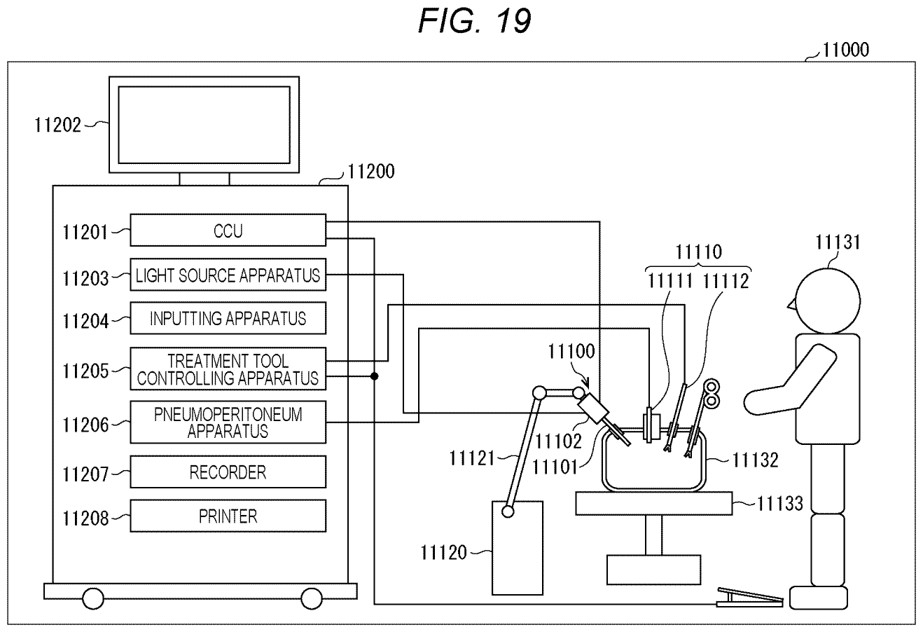

FIG. 19 is a diagram illustrating an example of a schematic configuration of the endoscopic surgery system to which the technology of the present disclosure (present technology) can be applied.

In FIG. 19, a state is depicted in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 is formed with a light source such as a light emitting diode (LED), for example, and supplies irradiation light for imaging a surgical region or the like to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

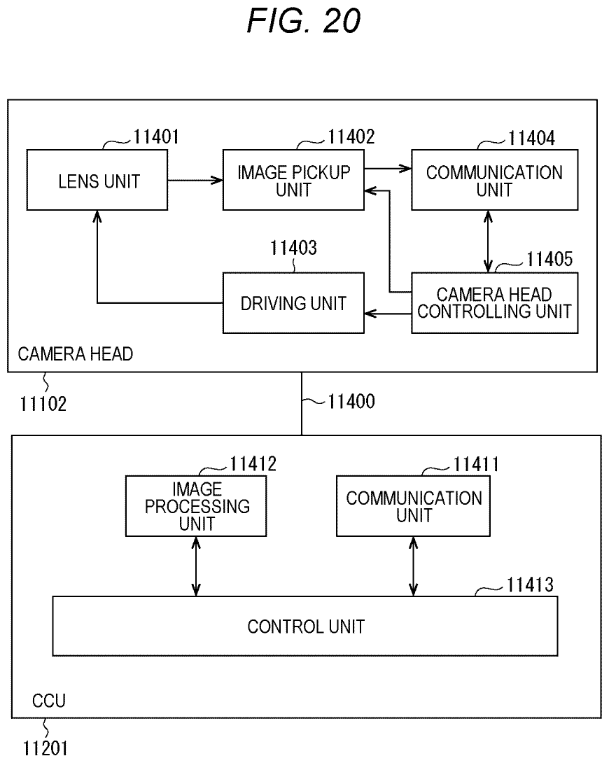

FIG. 20 is a block diagram illustrating an example of a functional configuration of the camera head 11102 and the CCU 11201 illustrated in FIG. 19.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may include a pair of image pickup elements for acquiring right-eye and left-eye image signals compatible with three-dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure yyAE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure can be applied to the lens unit 11401 and the image pickup unit 11402 of the camera head 11102 among the above-described components. For example, the photodetection device 1 as the IR imaging sensor having the configuration described in FIGS. 5 and 6 can be applied as the lens unit 11401 and the image pickup unit 11402. By applying the technology according to the present disclosure to the lens unit 11401 and the image pickup unit 11402, it is possible to obtain a clearer surgical region image while downsizing the camera head 11102.

Note that an endoscopic surgery system has been described as an example herein, but in addition, the technology according to the present disclosure may be applied to a microscopic surgery system or the like, for example.

### 13. Application Example to Mobile Body

The technology according to the present disclosure (present technology) can be applied to various products. For example, the technology according to the present disclosure may be implemented in the form of a device to be mounted on a mobile body of any kind, such as an automobile, an electric vehicle, a hybrid electric vehicle, a motorcycle, a bicycle, a personal mobility, an airplane, a drone, a vessel, or a robot.

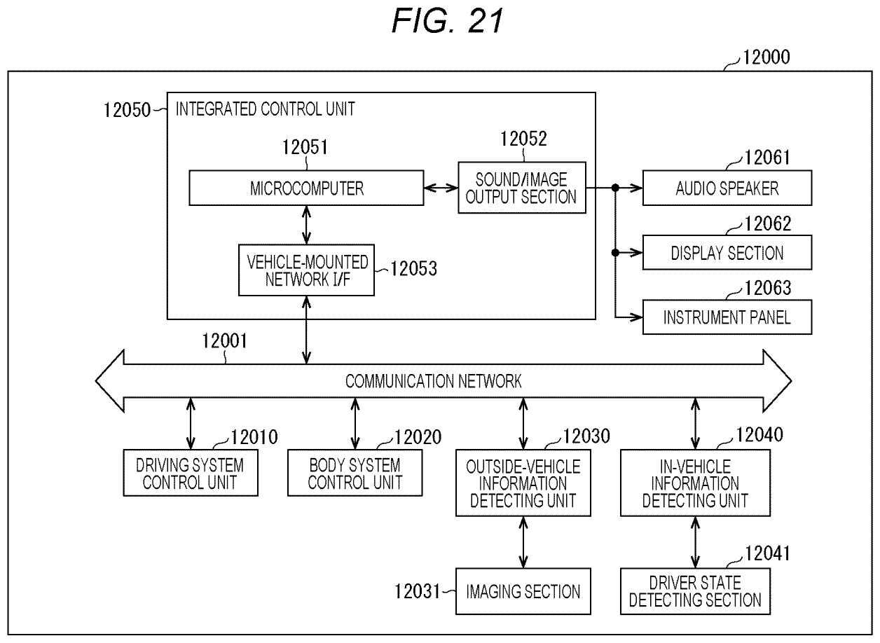

FIG. 21 is a block diagram illustrating an example of a schematic configuration of a vehicle control system that is an example of a mobile body control system to which the technology according to the present disclosure can be applied.

The vehicle control system 12000 includes a plurality of electronic control units connected to each other via a communication network 12001. In the example illustrated in FIG. 21, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are depicted as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020, on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

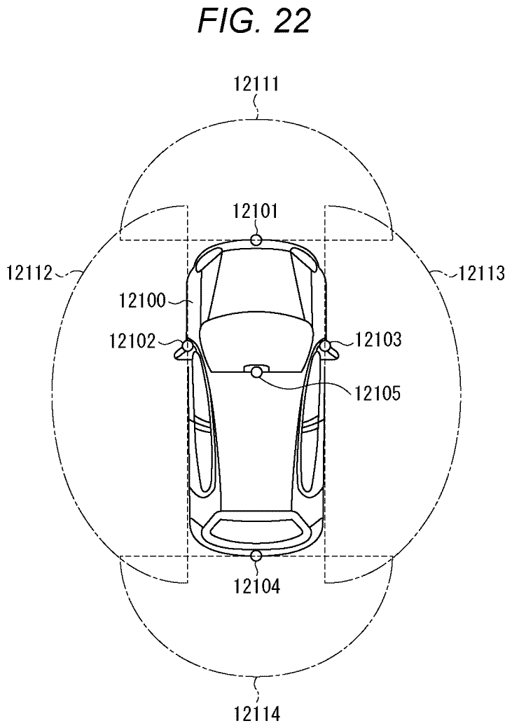

FIG. 22 is a diagram illustrating an example of installation positions of the imaging section 12031.

In FIG. 22, a vehicle 12100 includes imaging sections 12101, 12102, 12103, 12104, and 12105 as the imaging section 12031.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided on the sideview mirrors obtain mainly images of the sides of the vehicle 12100. The imaging section 12104 provided to the rear bumper or the back door obtains mainly an image of the rear of the vehicle 12100. Images of the front to be obtained by the imaging sections 12101 and 12105 are used mainly to detect a preceding vehicle, a pedestrian, an obstacle, a traffic signal, a traffic sign, a lane, or the like.

Note that FIG. 22 illustrates an example of an image capturing range of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the components described above. For example, the photodetection device 1 as the IR imaging sensor having the configuration described in FIGS. 5 and 6 can be applied as the imaging section 12031. Alternatively, the photodetection device 1 as the direct ToF sensor having the configuration described in FIGS. 9 and 10 can be applied as the imaging section 12031. By applying the technology according to the present disclosure to the imaging section 12031, it is possible to obtain easier-to-view captured images and obtain distance information while reducing the size. Furthermore, it is possible to reduce driver's fatigue and increase the safety of the driver and the vehicle, using the obtained captured images and distance information.

In the above-described example, the photodetection device has been described in which a first conductivity type is the P-type, a second conductivity type is the N-type, and electrons are used as signal charges, but the present disclosure can also be applied to a photodetection device in which holes are used as signal charges. That is, the first conductivity type may be the N-type, the second conductivity type may be the P-type, and the conductivity types of the above-described respective semiconductor regions may be reversed.

Furthermore, the present disclosure is not limited to application to a photodetection device that detects a distribution of the amount of incident light of visible light and captures the distribution as an image, and can be applied to all photodetection devices (physical quantity distribution detection apparatuses) such as a photodetection device that captures a distribution of the amount of incident infrared rays, X-rays, particles, or the like as an image, and a fingerprint detection sensor that detects a distribution of other physical quantities such as pressure and capacitance and captures the distribution as an image in a broad sense.

Embodiments of the present disclosure are not limited to the above-described embodiment, and various modifications may be made without departing from the scope of the technology of the present disclosure.

For example, a form can be adopted in which all or some of the components applied to the above-described pixels 200 are appropriately combined. Furthermore, in the above-described embodiment, an example has been described in which the photoelectric conversion section is formed in the SiGe layer 11, but a germanium layer may be adopted instead of the SiGe layer 11 in order to further increase the absorption coefficient in the infrared region.

Note that the effects described in the present specification are merely examples and are not restrictive, and there may be effects other than those described in the present specification.

Note that the technology of the present disclosure can have the following configurations.
(1)

A photodetection device including:
a silicon germanium layer on which a photoelectric conversion section is formed;
an inter-pixel light shielding film formed on a first surface side that is a light incident surface side of the silicon germanium layer; and
a MOS transistor formed on a second surface side that is an opposite side of the silicon germanium layer from the first surface, in which
a germanium concentration of the silicon germanium layer is formed at a constant concentration.
(2)

The photodetection device according to (1), in which
a variation in germanium concentration in the silicon germanium layer is formed to be smaller than 10%.
(3)

The photodetection device according to (1) or (2), further including
a silicon layer on an upper surface on the second surface side of the silicon germanium layer, in which
the MOS transistor is formed on the silicon layer.
(4)

The photodetection device according to any of (1) to (3), having a stacked configuration of:
a first semiconductor substrate including the silicon germanium layer; and
a second semiconductor substrate on which at least a logic circuit is formed, in which
the MOS transistor is formed on the second semiconductor substrate.
(5)

The photodetection device according to any of (1) to (4), in which
the photodetection device is a gate type ToF sensor including the photoelectric conversion section, a transfer transistor, an amplification transistor, a selection transistor, a reset transistor, and a charge discharge transistor in units of pixels.
(6)

The photodetection device according to any of (1) to (5), in which
the photodetection device is an imaging sensor including the photoelectric conversion section, a transfer transistor, an amplification transistor, a selection transistor, and a reset transistor in units of pixels.
(7)

The photodetection device according to any of (1) to (5), in which
the photodetection device is a CAPD type ToF sensor including, in units of pixels, the photoelectric conversion section, a voltage application section that applies a predetermined voltage to the photoelectric conversion section, and a charge detection section that detects a charge generated by the photoelectric conversion section.
(8)

The photodetection device according to any of (1) to (5), in which
the photodetection device is a direct ToF sensor including an avalanche photodiode including an avalanche multiplication region as the photoelectric conversion section, in units of pixels.
(9)

The photodetection device according to any of (1) to (8), further including
an element separation section that separates the photoelectric conversion section in units of pixels.
(10)

The photodetection device according to (9), in which
the element separation section has a tapered cross-sectional shape in which a groove width is narrowed from a back surface side toward a front surface side of the silicon germanium layer.
(11)

The photodetection device according to (9), in which
the element separation section has a reverse tapered cross-sectional shape in which a groove width is narrowed from a front surface side to a back surface side of the silicon germanium layer.
(12)

The photodetection device according to any of (9) to (11), in which
the element separation section is formed to penetrate the silicon germanium layer.
(13)

The photodetection device according to any of (9) to (11), in which
the element separation section is formed in a part in a depth direction of the silicon germanium layer without penetrating the silicon germanium layer.
(14)

The photodetection device according to any of (1) to (13), further including
a diffraction structure on the first surface side of the silicon germanium layer.
(15)

The photodetection device according to (14), further including
an element separation section that separates the photoelectric conversion section in units of pixels, in which
the diffraction structure is formed, from the first surface side of the silicon germanium layer, with a method identical to that for the element separation section.
(16)

The photodetection device according to any of (1) to (13), further including
a diffraction structure on the second surface side of the silicon germanium layer.
(17)

The photodetection device according to (16), further including
an element separation section that separates the photoelectric conversion section in units of pixels, in which
the diffraction structure is formed, from the second surface side of the silicon germanium layer, with a method identical to that for the element separation section.
(18)

The photodetection device according to any of (14) to (17), in which
the diffraction structure includes STI.
(19)

A method for manufacturing a photodetection device, the method including:
forming a photoelectric conversion section in a silicon germanium layer;
forming an inter-pixel light shielding film on a first surface side that is a light incident surface side of the silicon germanium layer; and
forming a MOS transistor on a second surface side that is an opposite side of the silicon germanium layer from the first surface, in which
a germanium concentration of the silicon germanium layer is formed at a constant concentration.
(20)

An electronic device including
a photodetection device including:
a silicon germanium layer on which a photoelectric conversion section is formed;
an inter-pixel light shielding film formed on a first surface side that is a light incident surface side of the silicon germanium layer; and
a MOS transistor formed on a second surface side that is an opposite side of the silicon germanium layer from the first surface, in which
a germanium concentration of the silicon germanium layer is formed at a constant concentration.

### REFERENCE SIGNS LIST

1 Photodetection device
11 SiGe layer
12 Photodiode
13 Element separation section
14 Antireflection film
15 Light shielding film
16 Lens layer
17 On-chip lens
21 Si layer
31 Gate insulating film
32 Gate electrode
33 Sidewall
43 Insulating layer
51 Semiconductor substrate
61 Wiring layer
66 Bonding surface
111 Silicon substrate
112 SiGe stress relieving layer
200 Pixel
321 Transfer transistor
323 Reset transistor
324 Amplification transistor
325 Selection transistor
331 P well
481 Diffraction structure
491 Diffraction structure
521 Pixel array unit
Tr MOS transistor
AMP Amplification transistor
FD Floating diffusion region
FDG Switching transistor
FDL Additional capacitor
OFG Charge discharge transistor
RST Reset transistor
SEL Selection transistor
TRG Transfer transistor

1. A photodetection device comprising:
a silicon germanium layer on which a photoelectric conversion section is formed;
an inter-pixel light shielding film formed on a first surface side that is a light incident surface side of the silicon germanium layer; and
a MOS transistor formed on a second surface side that is an opposite side of the silicon germanium layer from the first surface, wherein
a germanium concentration of the silicon germanium layer is formed at a constant concentration.

2. The photodetection device according to claim 1, wherein
a variation in germanium concentration in the silicon germanium layer is formed to be smaller than 10%.

3. The photodetection device according to claim 1, further comprising
a silicon layer on an upper surface on the second surface side of the silicon germanium layer, wherein
the MOS transistor is formed on the silicon layer.

4. The photodetection device according to claim 1, having a stacked configuration of:
a first semiconductor substrate including the silicon germanium layer; and
a second semiconductor substrate on which at least a logic circuit is formed, wherein
the MOS transistor is formed on the second semiconductor substrate.

5. The photodetection device according to claim 1, wherein
the photodetection device is a gate type ToF sensor including the photoelectric conversion section, a transfer transistor, an amplification transistor, a selection transistor, a reset transistor, and a charge discharge transistor in units of pixels.

6. The photodetection device according to claim 1, wherein
the photodetection device is an imaging sensor including the photoelectric conversion section, a transfer transistor, an amplification transistor, a selection transistor, and a reset transistor in units of pixels.

7. The photodetection device according to claim 1, wherein
the photodetection device is a CAPD type ToF sensor including, in units of pixels, the photoelectric conversion section, a voltage application section that applies a predetermined voltage to the photoelectric conversion section, and a charge detection section that detects a charge generated by the photoelectric conversion section.

8. The photodetection device according to claim 1, wherein
the photodetection device is a direct ToF sensor including an avalanche photodiode including an avalanche multiplication region as the photoelectric conversion section, in units of pixels.

9. The photodetection device according to claim 1, further comprising
an element separation section that separates the photoelectric conversion section in units of pixels.

10. The photodetection device according to claim 9, wherein
the element separation section has a tapered cross-sectional shape in which a groove width is narrowed from a back surface side toward a front surface side of the silicon germanium layer.

11. The photodetection device according to claim 9, wherein
the element separation section has a reverse tapered cross-sectional shape in which a groove width is narrowed from a front surface side to a back surface side of the silicon germanium layer.

12. The photodetection device according to claim 9, wherein
the element separation section is formed to penetrate the silicon germanium layer.

13. The photodetection device according to claim 9, wherein
the element separation section is formed in a part in a depth direction of the silicon germanium layer without penetrating the silicon germanium layer.

14. The photodetection device according to claim 1, further comprising
a diffraction structure on the first surface side of the silicon germanium layer.

15. The photodetection device according to claim 14, further comprising
an element separation section that separates the photoelectric conversion section in units of pixels, wherein
the diffraction structure is formed, from the first surface side of the silicon germanium layer, with a method identical to that for the element separation section.

16. The photodetection device according to claim 1, further comprising
a diffraction structure on the second surface side of the silicon germanium layer.

17. The photodetection device according to claim 16, further comprising
an element separation section that separates the photoelectric conversion section in units of pixels, wherein
the diffraction structure is formed, from the second surface side of the silicon germanium layer, with a method identical to that for the element separation section.

18. The photodetection device according to claim 14, wherein
the diffraction structure includes STI.

19. A method for manufacturing a photodetection device, the method comprising:
forming a photoelectric conversion section in a silicon germanium layer;
forming an inter-pixel light shielding film on a first surface side that is a light incident surface side of the silicon germanium layer; and
forming a MOS transistor on a second surface side that is an opposite side of the silicon germanium layer from the first surface, wherein
a germanium concentration of the silicon germanium layer is formed at a constant concentration.

20. An electronic device comprising
a photodetection device including:
a silicon germanium layer on which a photoelectric conversion section is formed;
an inter-pixel light shielding film formed on a first surface side that is a light incident surface side of the silicon germanium layer; and
a MOS transistor formed on a second surface side that is an opposite side of the silicon germanium layer from the first surface, wherein
a germanium concentration of the silicon germanium layer is formed at a constant concentration.
